(19) United States
(12) Patent Application Publication
(10) Pub. No.: US 2015/0076702 A1
(43) Pub. Date: Mar. 19, 2015

(54) SEMICONDUCTOR DEVICE AND METHOD OF MANUFACTURING THE SAME

(71) Applicant: KABUSHIKI KAISHA TOSHIBA, Minato-ku (JP)

(72) Inventors: Naoyuki IIDA, Yokkaichi (JP); Satoshi Nagashima, Yokkaichi (JP); Shoichi Miyazaki, Yokkaichi (JP); Ryota Nihei, Yokkaichi (JP)

(73) Assignee: KABUSHIKI KAISHA TOSHIBA, Minato-ku (JP)

(21) Appl. No.: 14/449,545

(22) Filed: Aug. 1, 2014

(30) Foreign Application Priority Data
Sep. 17, 2013 (JP) 2013-192058

(51) Int. Cl. H01L 23/485; H01L 21/8234; H01L 27/11; H01L 21/768; H01L 21/033

(52) U.S. Cl. CPC H01L 23/485; H01L 21/76838; H01L 21/033; H01L 27/11; H01L 21/8234
USPC 257/773; 438/666

(57) ABSTRACT

A semiconductor device including a semiconductor substrate having a hook-up region; wirings extending in a first direction above the semiconductor substrate and being aligned with a first spacing between one another, every two wirings forming pairs of wirings, each pair having a first portion being bent in a second direction different from the first direction in the hook-up region, the wirings of each pair being spaced from one another by a first spacing, the pairs being spaced from one another by a second spacing greater than the first spacing; and fringe patterns each being formed on a first side of each of the wirings of each of the pairs, the first side facing the second spacing.

### CROSS-REFERENCE TO RELATED APPLICATION(S)

This application is based upon and claims the benefit of priority from Japanese Patent Application No. 2013-192058, filed on, Sep. 17, 2013 the entire contents of which are incorporated herein by reference.

### FIELD

Embodiments disclosed herein generally relate to a semiconductor device and a method of manufacturing the same.

### BACKGROUND

With advances in microfabrication of semiconductor devices, formation of patterns narrower than the critical dimension achievable by photolithography is being required. For example, in manufacturing devices such as a NAND flash memory device, small patterns are formed by using a sidewall transfer technique. It is possible to form further smaller patterns by performing the sidewall transfer technique twice. Hook-up regions for forming contact portions may be provided at the end of the patterns. In such case, an additional lithography step is required to form the hook-up regions and thus, requires increased patterning cost. Further, it is desired to reduce the size of the hook-up portions for further shrinking of the semiconductor device.

### BRIEF DESCRIPTION OF THE DRAWINGS

FIG. 1 is one example partially illustrating an electrical configuration of a memory-cell region of a NAND Flash memory device of a first embodiment.

FIG. 2 is one example of a schematic plan view of the memory-cell region.

FIG. 3A is one example of a plan view of a word line hook-up part.

FIG. 3B is one schematic example of a vertical cross-sectional view taken along line 3B-3B of FIG. 3A.

FIG. 3C is one schematic example of a vertical cross-sectional view taken along line 3C-3C of FIG. 2.

FIG. 4A is one example of a plan view of a word line hook-up part in one phase of the manufacturing process flow.

FIG. 4B is one schematic example of a vertical cross-sectional view taken along line 4B-4B of FIG. 4A.

FIG. 5A is one example of a plan view of a word line hook-up part in one phase of the manufacturing process flow.

FIG. 5B is one schematic example of a vertical cross-sectional view taken along line 5B-5B of FIG. 5A.

FIG. 6A is one example of a plan view of a word line hook-up part in one phase of the manufacturing process flow.

FIG. 6B is one schematic example of a vertical cross-sectional view taken along line 6B-6B of FIG. 6A.

FIG. 7A is one example of a plan view of a word line hook-up part in one phase of the manufacturing process flow.

FIG. 7B is one schematic example of a vertical cross-sectional view taken along line 7B-7B of FIG. 7A.

FIG. 8A is one example of a plan view of a word line hook-up part in one phase of the manufacturing process flow.

FIG. 8B is one schematic example of a vertical cross-sectional view taken along line 8B-8B of FIG. 8A.

FIG. 9A is one example of a plan view of a word line hook-up part in one phase of the manufacturing process flow.

FIG. 9B is one schematic example of a vertical cross-sectional view taken along line 9B-93 of FIG. 9A.

FIG. 10A is one example of a plan view of a word line hook-up part in one phase of the manufacturing process flow.

FIG. 10B is one schematic example of a vertical cross-sectional view taken along line 10B-10B of FIG. 10A.

FIG. 11A is one example of a plan view of a word line hook-up part in one phase of the manufacturing process flow.

FIG. 11B is one schematic example of a vertical cross-sectional view taken along line 11B-11B of FIG. 11A.

FIG. 12A illustrates a second embodiment and is one schematic example of a vertical cross-sectional view taken along line 3C-3C of FIG. 2.

FIG. 12B is one example of a plan view of the word line hook-up part.

FIG. 12C is one schematic example of a vertical cross-sectional view taken along line 12C-12C of FIG. 12B.

FIG. 12D is one schematic example of a vertical cross-sectional view taken along line 12D-12D of FIG. 12B.

FIG. 13A is one schematic example of a vertical cross-sectional view taken along line 3C-3C of FIG. 2 in one phase of the manufacturing process flow.

FIG. 13B is one example of a plan view of a word line hook-up part in one phase of the manufacturing process flow.

FIG. 14A is one schematic example of a vertical cross-sectional view taken along line 3C-3C of FIG. 2 in one phase of the manufacturing process flow.

FIG. 14B is one example of a plan view of a word line hook-up part in one phase of the manufacturing process flow.

FIG. 15A is one schematic example of a vertical cross-sectional view taken along line 3C-3C of FIG. 2 in one phase of the manufacturing process flow.

FIG. 15B is one example of a plan view of a word line hook-up part in one phase of the manufacturing process flow.

FIG. 16A is one schematic example of a vertical cross-sectional view taken along line 3C-3C of FIG. 2 in one phase of the manufacturing process flow.

FIG. 16B is one example of a plan view of a word line hook-up part in one phase of the manufacturing process flow.

FIG. 17A is one schematic example of a vertical cross-sectional view taken along line 3C-3C of FIG. 2 in one phase of the manufacturing process flow.

FIG. 17B is one example of a plan view of a word line hook-up part in one phase of the manufacturing process flow.

FIG. 18A is one schematic example of a vertical cross-sectional view taken along line 3C-3C of FIG. 2 in one phase of the manufacturing process flow.

FIG. 18B is one example of a plan view of a word line hook-up part in one phase of the manufacturing process flow.

FIG. 19A is one schematic example of a vertical cross-sectional view taken along line 3C-3C of FIG. 2 in one phase of the manufacturing process flow.

FIG. 19B is one example of a plan view of a word line hook-up part in one phase of the manufacturing process flow.

FIG. 20 is a modified example of a fringe pattern.

FIG. 21 is another modified example of the fringe pattern.

FIG. 22 illustrates a third embodiment and is one example of a plan view of a word line hook-up part in one phase of the manufacturing process flow.

FIG. 23 is one example of a plan view of a word line hook-up part in one phase of the manufacturing process flow.

FIG. 24 is one example of a plan view of a word line hook-up part in one phase of the manufacturing process flow.

FIG. 25 is one example of a plan view of a word line hook-up part in one phase of the manufacturing process flow.

FIG. 26 illustrates a fourth embodiment and is one example of a plan view of a word line hook-up part in one phase of the manufacturing process flow.

FIG. 27 is one example of a plan view of a word line hook-up part in one phase of the manufacturing process flow.

FIG. 28 is one example of a plan view of a word line hook-up part in one phase of the manufacturing process flow.

FIG. 29 is one example of a plan view of a word line hook-up part in one phase of the manufacturing process flow.

FIG. 30 illustrates a fifth embodiment and is one example of a plan view of a word line hook-up part in one phase of the manufacturing process flow.

FIG. 31 is one example of a plan view of a word line hook-up part in one phase of the manufacturing process flow.

FIG. 32 is one example of a plan view of a word line hook-up part in one phase of the manufacturing process flow.

FIG. 33 is one example of a plan view of a word line hook-up part in one phase of the manufacturing process flow.

FIG. 34 is one example of a plan view of a word line hook-up part in one phase of the manufacturing process flow.

FIG. 35 is one example of a plan view of a word line hook-up part in one phase of the manufacturing process flow.

FIG. 36 illustrates a sixth embodiment and is one example of a plan view of a word line hook-up part in one phase of the manufacturing process flow.

FIG. 37 is one example of a plan view of a word line hook-up part in one phase of the manufacturing process flow.

FIG. 38 is one example of a plan view of a word line hook-up part in one phase of the manufacturing process flow.

FIG. 39 is one example of a plan view of a word line hook-up part in one phase of the manufacturing process flow.

FIG. 40 is one example of a plan view of a word line hook-up part in one phase of the manufacturing process flow.

FIG. 41 is one example of a plan view of a word line hook-up part in one phase of the manufacturing process flow.

FIG. 42 illustrates a seventh embodiment and is one example of a plan view of a word line hook-up part in one phase of the manufacturing process flow.

FIG. 43 is one example of a plan view of a word line hook-up part in one phase of the manufacturing process flow.

FIG. 44 is one example of a plan view of a word line hook-up part in one phase of the manufacturing process flow.

FIG. 45 is one example of a plan view of a word line hook-up part in one phase of the manufacturing process flow.

FIG. 46 illustrates an eighth embodiment and is one example of a plan view of a word line hook-up part in one phase of the manufacturing process flow.

FIG. 47 is one example of a plan view of a word line hook-up part in one phase of the manufacturing process flow.

FIG. 48 is one example of a plan view of a word line hook-up part in one phase of the manufacturing process flow.

FIG. 49 is one example of a plan view of a word line hook-up part in one phase of the manufacturing process flow.

FIG. 50 is a modified example of a fringe pattern.

FIG. 51 is another modified example of the fringe pattern.

FIG. 52 illustrates an ninth embodiment and is one example of a plan view of a word line hook-up part in one phase of the manufacturing process flow.

FIG. 53 is one example of a plan view of a word line hook-up part in one phase of the manufacturing process flow.

### DESCRIPTION

In one embodiment, a semiconductor device including a semiconductor substrate having a hook-up region; wirings extending in a first direction above the semiconductor substrate and being aligned with a first spacing between one another, every two wirings forming pairs of wirings, each pair having a first portion being bent in a second direction different from the first direction in the hook-up region, the wirings of each pair being spaced from one another by a first spacing, the pairs being spaced from one another by a second spacing greater than the first spacing; and fringe patterns each being formed on a first side of each of the wirings of each of the pairs, the first side facing the second spacing.

### EMBODIMENTS

Embodiments are described hereinafter through a NAND flash memory device application with references to the drawings. The drawings are schematic and are not drawn to scale and thus, do not reflect the actual measurements of the features such as the correlation of thickness to planar dimensions and the relative thickness of different layers. Further, directional terms such as up, down, left, and right are used in a relative context with an assumption that the worked surface, on which circuitry is formed of the later described semiconductor substrate faces up. Thus, the directional terms do not necessarily correspond to the directions based on gravitational acceleration.

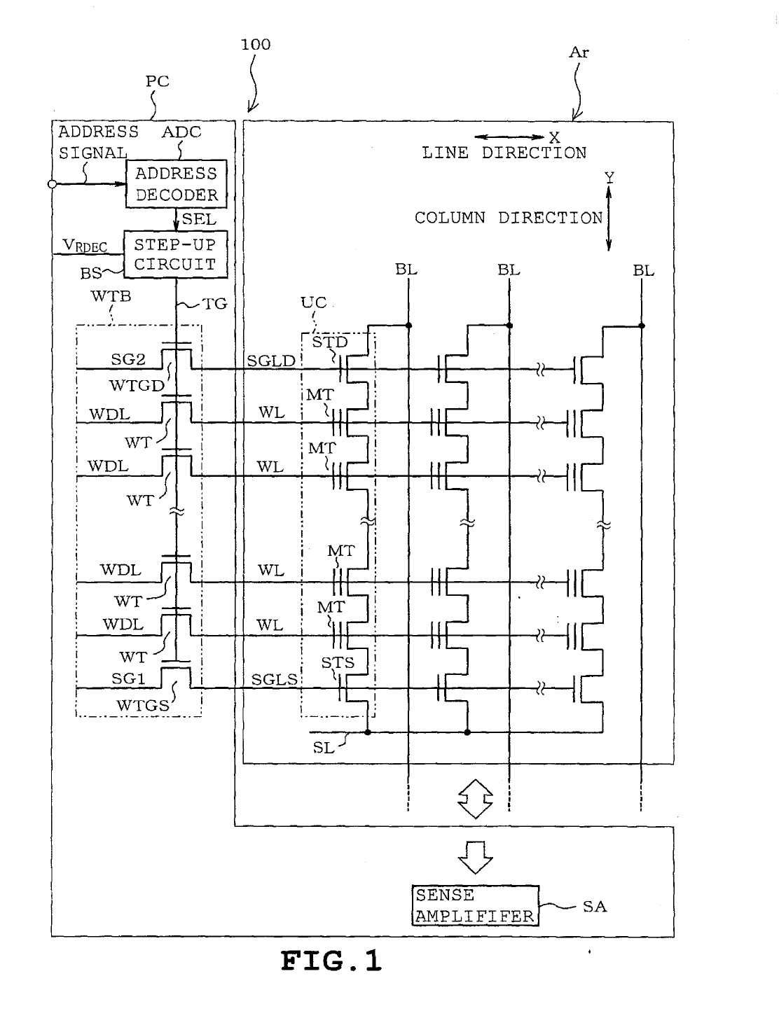

FIGS. 1 to 11 illustrate a first embodiment. FIG. 1 is one schematic example of a block diagram illustrating an electrical configuration of NAND flash memory device according to one embodiment. As shown in FIG. 1, NAND flash memory device 100 is provided with memory cell array Ar, peripheral circuit PC, and input/output interface circuitry not shown. Memory cell array Ar is configured by memory cells arranged in a matrix. Peripheral circuit PC is configured to read/program/erase each of the memory cells in memory cell array Ar.

Cell units UC are disposed in memory cell array Ar located in the memory cell region. Each cell unit UC has 2^{k} number (for example k=32) of series connected memory-cell transistors MT situated between a couple of select transistors STD and STS. Select transistors STD are connected to bit lines BL, and select transistors STS are connected to source lines SL.

A block includes n number of cell units UC aligned in the X direction (row direction: the left and right direction as viewed in FIG. 1). Memory cell array Ar includes multiple blocks aligned in the Y direction (column direction: the up and down direction in FIG. 1). FIG. 1 only shows one block for simplicity.

The memory-cell region is surrounded by a peripheral-circuit region and peripheral circuit PC is located in the periphery of memory cell array Ar. Peripheral circuit PC is provided with address decoder ADC, sense amplifier SA, step-up circuit BS having a charge pump circuit, and transfer transistors WTB. Address decoder ADC is electrically connected to transfer transistor portion WTB through step-up circuit BS.

Address decoder ADC selects a given block based on an incoming address signal provided from an external component and sends block selection signal SEL to step-up circuit BS. Step-up circuit BS, when given a block selection signal, steps up drive voltage VRDEC received from an external component and supplies the stepped up voltage, being stepped up to a predetermined level, to transfer transistors WTGD, WTGS, and WT by way of transfer gate line TG.

Transfer transistor portion WTB is provided with transfer gate transistor WTGD, transfer gate transistor WTGS, word line transfer gate transistors WT, or the like. Transfer transistor portion WTB is given on a block by block basis.

Transfer gate transistor WTGD is configured such that either of the drain and source is connected to select gate driver line SG2, and the remaining other is connected to select gate line SGLD. Transfer gate transistor WTGS is configured such that either of the drain and source is connected to select gate driver line SG1, and the remaining other is connected to select gate line SGLS. Each of word line transfer gate transistor WT is configured such that either of the drain and source is uniquely connected to word line drive signal line WDL respectively, and the remaining other is uniquely connected to word line WL provided in memory-cell array Ar.

Gate electrodes SG of select transistors STD of cell units UC aligned in the X direction are electrically connected by a common select gate line SGLD. Similarly, gate electrodes SG of select transistors STS of cell units UC aligned in the X direction are electrically connected by a common select gate line SGLS. As described earlier, the source of each select transistor STS is connected to common source line SL. Gate electrodes MG of memory-cell transistors MT of cell units UC aligned in the X direction are electrically connected by a common word line WL respectively.

Gate electrodes of transfer transistors WTGD, WTGS, and WT are interconnected by common transfer gate line TG and transfer gate line TG is connected to an output terminal of step up circuit BS for supplying stepped up voltage.

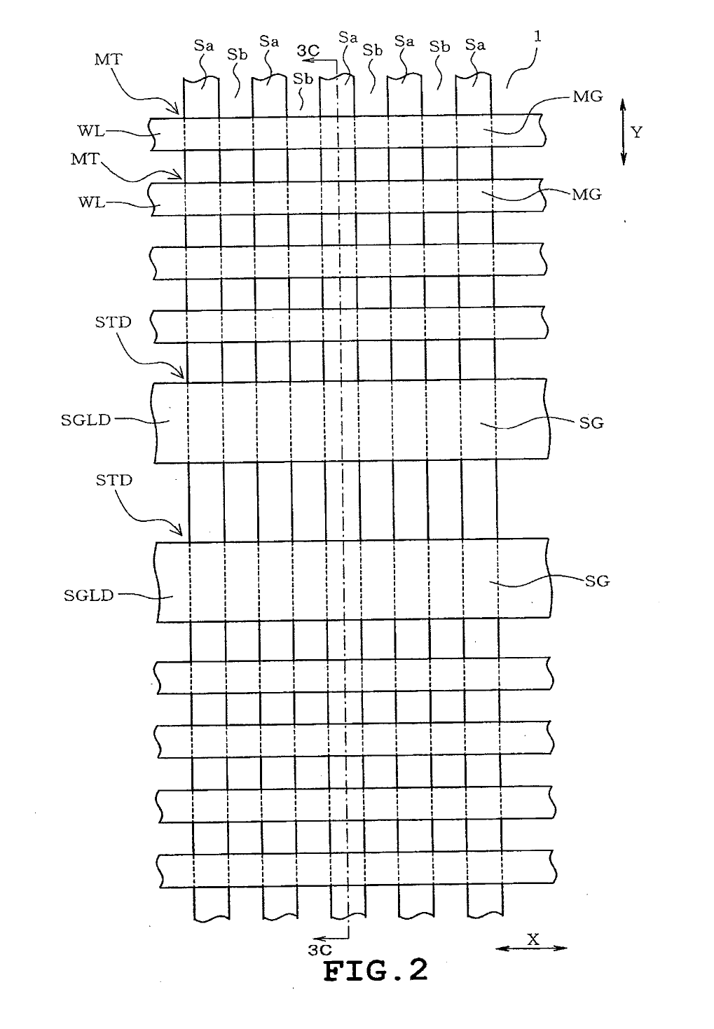

FIG. 2 is one example of a plan view of a layout of a portion of the memory-cell region. FIG. 2 does not show bit-line contacts CB. As shown in FIG. 2, a P-type silicon substrate or the like is used as semiconductor substrate 1. Element isolation regions Sb are formed so as to extend in the Y direction of the memory-cell region as viewed in FIG. 2. Element isolation regions Sb take an STI (shallow trench isolation) structure in which element isolation trenches 2d formed into the surface of semiconductor substrate 1 are filled with insulation materials. Element isolation regions Sb are formed so as to be spaced from one another in the X direction. Element isolation regions Sb isolate the surface of semiconductor substrate 1 serving as element region Sa in the X direction. As a result, element regions Sa are formed so as to extend along the Y direction of FIG. 2.

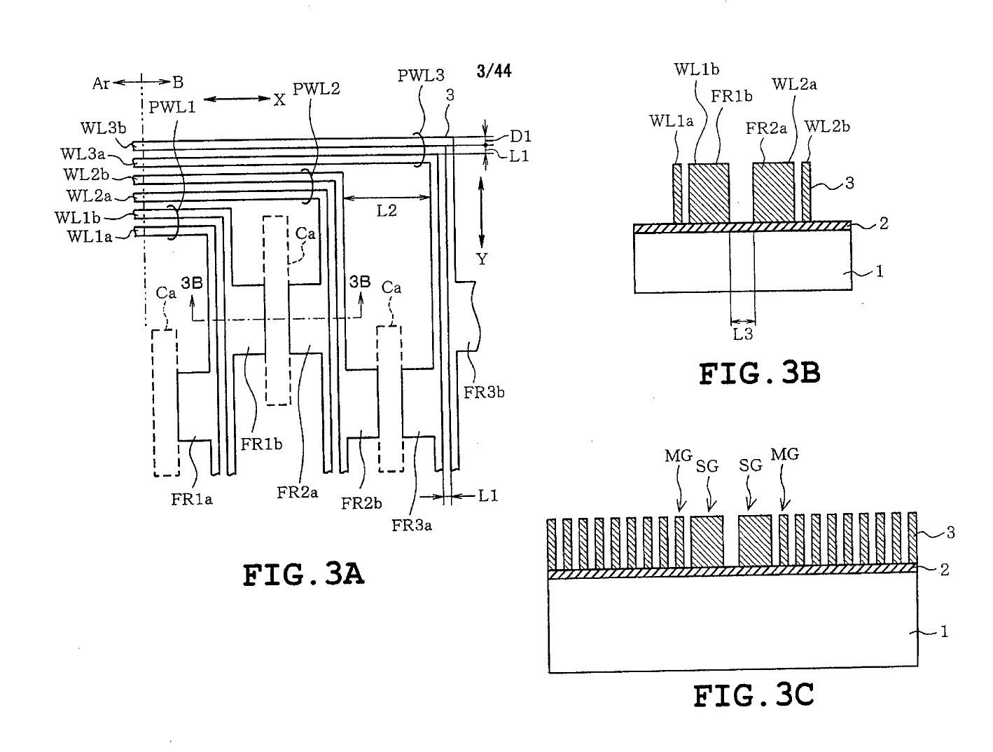

Word lines WL serving as wirings are disposed so as to extend along a direction orthogonal to element regions Sa (the X direction in FIG. 2). Word lines WL are formed so as to be isolated from one another in the Y direction as viewed in FIG. 2. Gate electrodes MG of memory-cell transistors MT (see FIG. 3C) are formed above element regions Sa crossing word lines WL.

Memory-cell transistors MT adjacent in the Y direction constitute a part of NAND string (memory-cell string). Select transistors (STD/STS) are disposed on the Y-direction outer sides of memory-cell transistors MT at both ends of the NAND string so as to be adjacent to memory-cell transistors MT. Select transistors STD (STS) are disposed in the X direction and gate electrodes SG of select transistors STD and STS are electrically connected by select gate lines SGLD and SGLS. Gate electrodes SG of select transistors STD and STS are disposed above element regions located at the intersection with select gate lines SGLD and SGLS.

FIG. 3A is one example of a plan view schematically illustrating a part of hook-up regions located in the peripheral circuit region. Word lines WL extending from the memory-cell region are disposed in hook-up regions in which contacts are formed. Further, FIG. 3B schematically illustrates a cross-section of a portion taken along line 3B-3B of FIG. 3A. Word lines WL serving as wirings extending from the memory cell region are formed as hook-up patterns in hook-up regions B. Above word lines WL, contacts are disposed which electrically connect to the metal layers through the interlayer insulating film. FIG. 3C illustrates a cross-section of a portion taken along line 3C-3C of FIG. 2. More specifically, FIG. 3C illustrate cross-sections of gate electrodes MG of memory-cell transistors and select gate electrodes SG of select transistors of the memory-cell region.

Each word line WL has first width D1 and extends in the row direction, in other words, the X direction. Word lines WL are spaced from one another by first space L1. Word lines WL are disposed in hook-up regions B so as to be bent in the column direction, in other words, the Y direction. In the portions where word lines WL are bent in the Y direction, two word lines WL are arranged in pairs such as paired word-lines PWL1, PWL2, PWL3, . . . . Word lines WL1a and WL1b form paired word-lines PWL1, word lines WL2a and WL2b form paired word-lines PWL2, and world lines WL3a and WL3b form paired word-lines PWL3 and word lines of each pair are spaced from one another by first space L1. Further, word lines WL1b and WL2a as well as word lines WL2b and WL3a are spaced from one another by second space L2. Second space L2 is greater than first space L1.

Each of word lines WL1a, WL1b, WL2a, WL2b, WL3a, and WL3b has fringe patterns FR1a, FR1b, FR2a, FR2b, FR3a, and FR3b, respectively. Fringe pattern FR1a of word line WL1a and fringe pattern FR1b of word line WL1b project toward the relatively wide second space L2. The boundary of hook-up region B is located between memory-cell array region Ar and fringe patterns FR.

Further, fringe patterns FR (FR1a, FR1b, FR2a, FR2b, FR3a, and FR3b) are formed in the regions having second space L2 where fringe pattern FR1b faces and fringe pattern FR2a and fringe pattern FR2b faces fringe pattern FR3a. The pairs are displaced in the Y direction from one another.

Next, as shown in FIG. 3B, gate insulating film 2 is formed above the upper surface of semiconductor substrate 1. Word lines WL1a, WL1b, and WL2a, and WL2b are formed above gate insulating film 2. The film structure of word lines WL are substantially the same as the film structure of memory-cell gate electrodes MG of memory-cell transistors MT. For example, word lines WL are formed of floating-gate electrode films, interelectrode insulating films, and control-gate electrode films stacked above gate insulating films 2. In the present application, the entire gate electrode MG is referred to as word line WL serving as a wiring and is illustrated without showing the details of the film structure.

In FIG. 3A corresponding to FIG. 3B, word line WL1a has first width D1 and extends in the Y direction. Word line WL1b has first width D1 and is spaced from word line WL1a by first space L1. In the portion illustrated in FIG. 3B, fringe pattern FR1b is formed in one with word line WL1b. Similarly, word line WL2a adjacent to word line WL1b has first width D1 and extends in the Y direction. Word line WL2b has first width D1 and is spaced from word line WL2a by first space L1. In the portion illustrated in FIG. 3B, fringe pattern FR2a is formed in one with word line WL2a. Further, FR1b and FR2a are spaced from one another by third space L3. The portions indicated by broken line in FIG. 3B are regions for forming patterns for cutting fringe patterns FR1b and FR2a in the later described manufacturing process flow.

Referring now to FIG. 3C, gate insulating films 2 are disposed above semiconductor substrate 1. Gate electrodes MG of memory-cell transistors and gate electrodes SG of select transistors are disposed above the upper surfaces of gate insulating films 2. Gate electrodes MG and SG are formed by processing gate electrode film 3. Gate electrode film 3 is formed by stacking floating gate electrode films, interelectrode insulating films, and control gate electrode films one over the other so that the resulting structure operates as NAND flash memory device 100. In the description given herein, the entire gate electrode MG and gate electrode SG are referred to as gate electrode film 3.

According to the above described structure, it is possible to dispose fringe patterns FR (FR1a to FR3b) of word lines WL (WL1a to WL3b) in hook-up regions B of word lines WL efficiently and in smaller spaces.

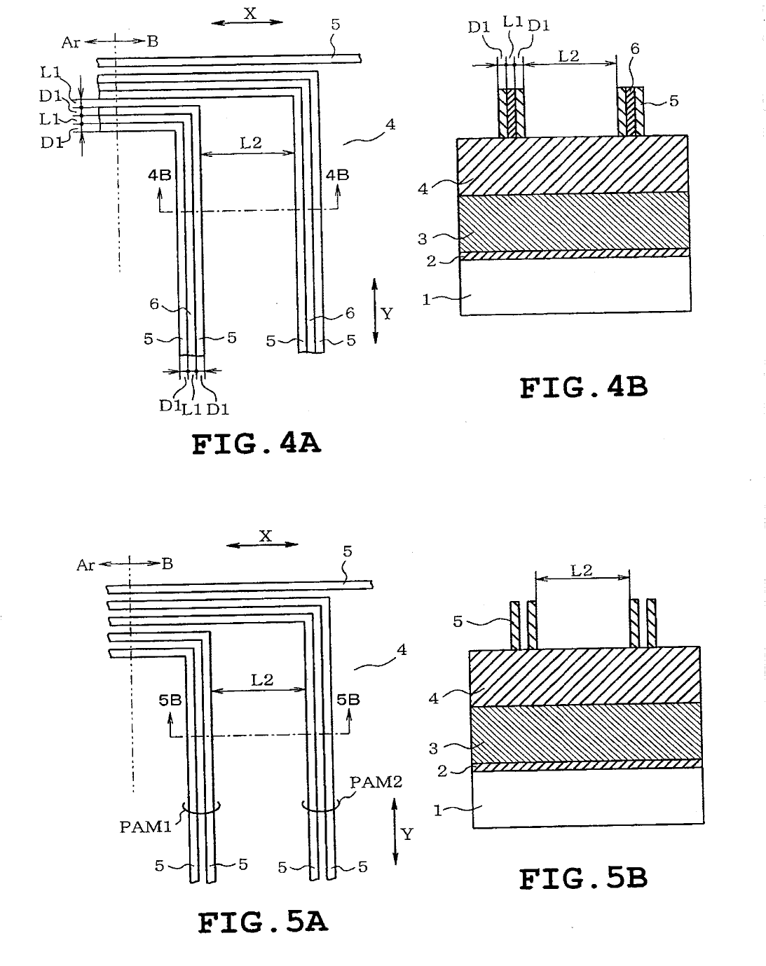

Next, a description will be given on the manufacturing process flow of the above described structure with reference to FIGS. 4A to 11B.

The structures illustrated in FIGS. 4A and 4B are formed of gate insulating film 2, gate electrode film 3, and insulating film 4 serving as a first processing film stacked above semiconductor substrate 1. Mandrel patterns 6 having sidewall patterns 5 formed along both side surfaces are formed above the stacked films. Gate electrode film 3 serving as the conductive layer of the wiring is a stacked film for forming gate electrodes MG of memory-cell transistors MT, gate electrodes SG of select transistors STD and STS, gate electrodes of transistors in peripheral-circuit region PC, and word lines. Gate electrode film 3 is formed of for example a conductive film serving as a floating gate electrode, an interelectrode insulating film, and a conductive film serving as a control gate electrode stacked above gate insulating film 2. Further, gate electrode film 3 constitutes a portion of word lines WL1a, WL1b, WL2a, and WL2b and a portion of patterns extending into hook-up regions B.

In the above described structure, each of insulating film 4 serving as the first processing film and sidewall pattern 5 and mandrel pattern 6 both serving as a second processing film are made of different materials. Thus, it is possible to selectively etch the foregoing films by RIE (reactive ion etching) or a wet process. For example, a silicon oxide film, a silicon nitride film, and a silicon film (polycrystalline silicon film or amorphous silicon film) may be used uniquely as insulating film 4, sidewall pattern 5, and mandrel pattern 6. As a result, it is possible to etch the foregoing films independently and selectively.

Mandrel patterns 6 are formed as line-and-space patterns having a line width and a space width which are each approximately twice the size of first width D1. The line width of mandrel patterns 6 is thereafter reduced to first width D1 by a slimming process. Mandrel patterns 6 are spaced from one another by a space width which is approximately 3 times of first width D1. Two sidewall patterns 5 form a pair and serves as a paired wiring mask. The paired wiring masks are shaped like spacers and are formed by forming a conformal film extending along insulating film 4 and along the side surfaces and upper surfaces of mandrel patterns 6 and etching back the conformal film by RIE or the like. Each sidewall pattern 5 has first width D1. Paired wiring masks PAM1, PAM2, . . . correspond to paired word-lines PWL1, PWL2, . . . , respectively.

Next, as shown in FIGS. 5A and 5B, mandrel patterns 6 are selectively removed by a wet process or the like. As a result, sidewall patterns 5 remain above insulating film 4. Sidewall patterns 5 are used as masks for patterning gate electrode film 3 into patterns of word lines WL. In hook-up region B, paired wiring masks PAM1 and PAM2 are disposed in the X direction so as to be spaced from one another by space L2.

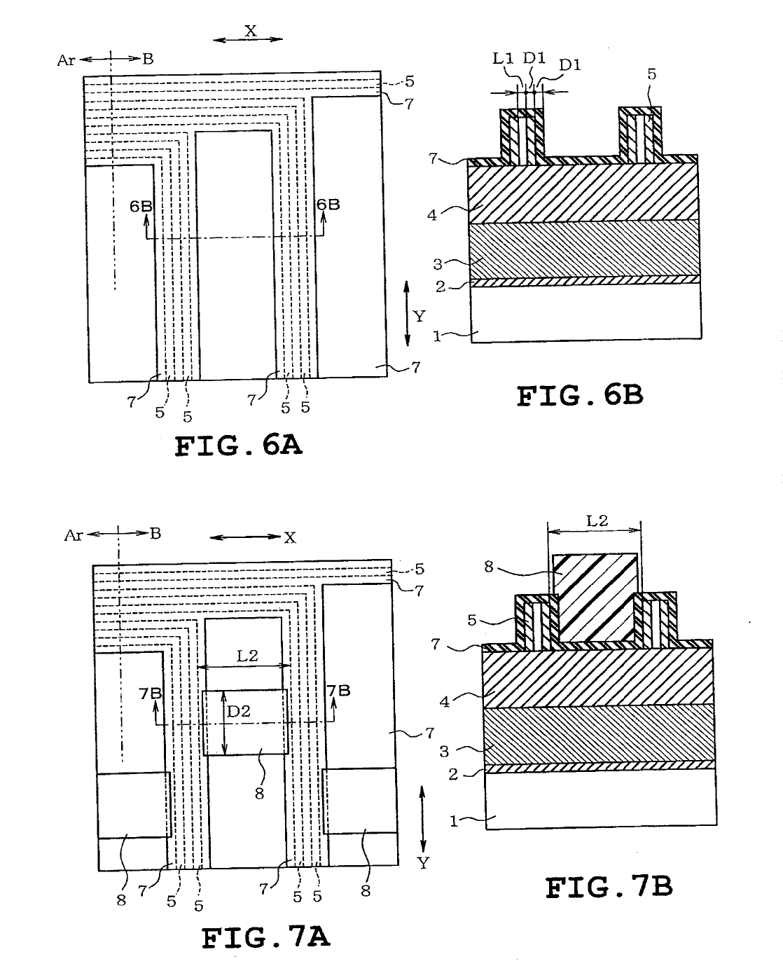

Then, as shown in FIGS. 6A and 6B, insulating film 7 having thickness D1 is formed by CVD (chemical vapor deposition) under conditions having poor coverage. As a result, insulating film 7 is not formed between sidewall patterns 5 in portions where sidewall patterns 5 are spaced from one another by first space L1. In such portions, insulating film 7 extends continuously above the upper surfaces of sidewall patterns 5. Thus, insulating film 7 is not formed between sidewall patterns 5 in portions where sidewall patterns 5 extend in the X direction. Further, in hook-up region B, sidewall patterns 5 of each paired wiring mask are spaced from one another by first space L1 in the portions before sidewall patterns 5 are bent. Thus, insulating film 7 is not formed in such portions. On the other hand, the paired wiring masks PAM are spaced from one another by second space L2. Thus, insulating film 7 is formed between paired wiring masks PAM. In other words, insulating film 7 serves a third processing film formed along the side surfaces and upper surfaces of sidewall patterns 5 and above insulating film 4.

Then, as shown in FIGS. 7A and 7B, a resist film is formed above insulating film 7 and the resist film is patterned by lithography to form resist patterns 8 in hook-up region B. Resist patterns 8 are formed at widths equal to or greater than second space L2 so as to fill the gaps between paired wiring masks PAM. Each resist pattern 8 has width D2 in the Y direction. Resist patterns 8 adjacent in the X direction are displaced from one another in the Y direction so as not to overlap in the Y direction. In other words, resist patterns 8 are disposed in a zigzag layout. The X-direction ends of the resist patterns 8 are located above the upper surfaces of paired wiring masks PAM or along insulating film 7 disposed along the side surfaces of paired wiring masks PAM. Resist patterns 8 are formed so as to cover the recesses between sidewall patterns 5 of paired wiring patterns PAM.

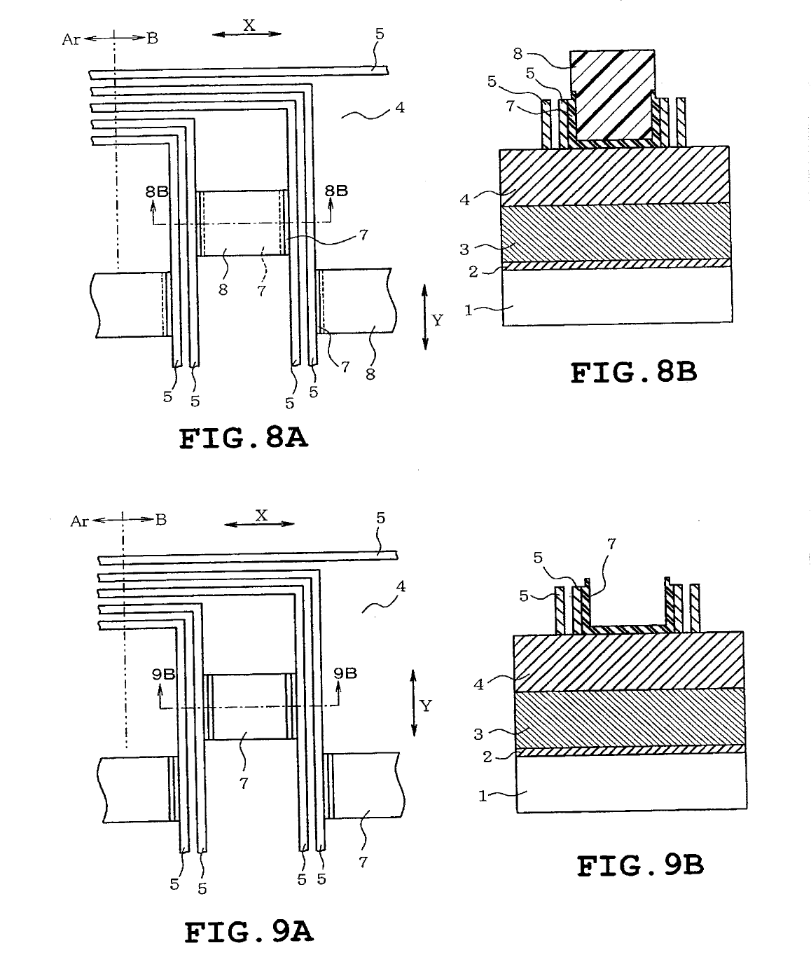

Then, as shown in FIGS. 8A and 8B, insulating film 7 is selectively etched by RIE or a wet process using resist patterns 8 as masks. As a result, insulating films 7 remain in the areas where fringe patterns FR are to be formed and serves as masks in the subsequent step. It is possible to remove insulating films remaining above paired wiring masks PAM in this step. Then, as shown in FIGS. 9A and 9B, resist patterns 8 are removed by SPM (sulfo-peroxide-mixture) cleaning or ashing.

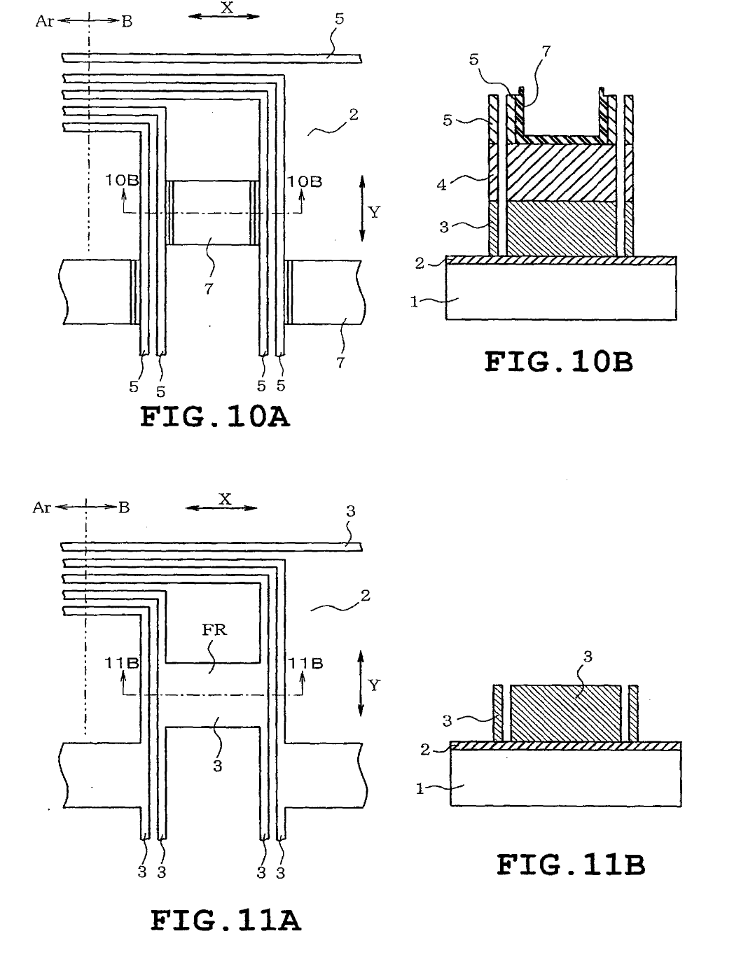

Then, as shown in FIGS. 10A and 10B, insulating film 4 and gate electrode film 3 are etched by RIE using sidewall patterns and insulating films 7 as masks. It is possible to carry out the etching for example in the step for forming gate electrodes MG of memory-cell transistors and gate electrodes SG of select transistors.

Then, as shown in FIGS. 11A and 11B, sidewall patterns 5, insulating films 7, and insulating films 4 are selectively removed. It is thus possible to obtain word lines WL formed of gate electrode films 3, interlinked fringe patterns FR, gate electrodes MG, SG, and the like.

Then, as shown in FIGS. 3A and 3B, the interlinked fringe patterns FR are divided at the X-direction central portion. The dividing of fringe patterns FR is carried out by forming openings Ca indicated by broken lines in FIG. 3A with resist patterns by photolithography and removing gate electrode films 3 exposed by openings Ca by RIE. Thus, divided fringe patterns FR1a, FR1b, FR2a, and FR2b are formed as shown in FIGS. 3A and 3B.

In the first embodiment described above, word lines WL are arranged as paired word lines WL in hook-up region B. Further, it is possible to form fringe pattern FR to each of word lines WL of paired word-lines PWL. As a result, it is possible to reduce the spaces required for forming fringe patterns FR.

Further in the first embodiment, paired wiring masks PAM are bent in the Y direction so as to be spaced from one another by second space L2. Thus, it is possible to form fringe patterns without a lithography step for increasing the space between word lines WL. As a result, it is possible to simplify the manufacturing process flow.

The first embodiment was described through an example in which gate electrode film 3 is processed to form word lines WL. Fringe patterns for contacts using wiring patterns of normal wiring layers for example may be formed in a similar manner.

### Second Embodiment

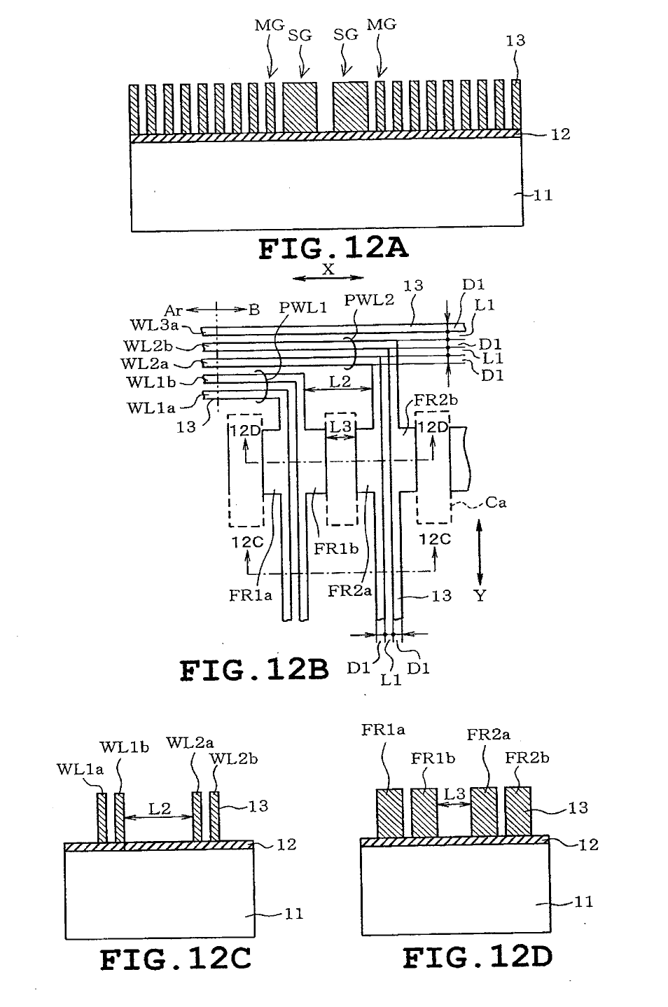

FIGS. 12A to 21 illustrate a second embodiment. The second embodiment differs from the first embodiment in that the manufacturing process step progresses in conjunction with the processing of the memory-cell region.

FIG. 12A illustrates a cross section of a portion taken along line 3C-3C of FIG. 2, that is, a cross section of gate electrodes MG of memory-cell transistors and gate electrodes SG of select transistors in the memory-cell region. Gate insulating film 12 is disposed above semiconductor substrate 11. Gate electrodes MG of memory-cell transistors and gate electrodes SG of select transistors are disposed above the upper surface of gate insulating film 12. Gate electrodes MG and SG are formed by processing gate electrode film 13.

Gate electrode film 13 is formed of floating gate electrode films, interelectrode insulating films, and control gate electrode films stacked one over the other so that the resulting structure operates as NAND flash memory device 100 as was the case for gate electrode film 3 in the first embodiment. In the description given herein, the entire gate electrode MG and gate electrode SG are referred to as gate electrode film 13.

FIG. 12B illustrates word lines WL formed by processing gate electrode films 13 and fringe patterns formed in hook-up region B. The widths of word lines WL and spaces between word lines WL are substantially the same as those of the first embodiment.

Each word line WL has first width D1 and extends in the X direction. Word lines WL are spaced from one another in the Y direction by first space L1. Word lines WL are disposed in hook-up regions B so as to be bent in the column direction, in other words, the Y direction. In the portions where word lines WL are bent in the Y direction, two word lines WL are arranged in pairs such as paired word-lines PWL1, PWL2, . . . . Word lines WL1a and WL1b form paired word-lines PWL1 and word lines WL2a and WL2b form paired word-lines PWL2 and word lines of each pair are spaced from one another by first space L1. Further, word lines WL1b and WL2a are spaced from one another in the X direction by second space L2. Second space L2 is greater than first space L1.

Each of word lines WL1a, WL1b, WL2a, WL2b, has fringe patterns FR1a, FR1b, FR2a, and FR2b respectively. Fringe patterns FR1a, FR1b, FR2a, and FR2b are rectangular and are used for forming contacts. Fringe patterns FR1a and FR1b of word lines WL1a and WLb1 and fringe patterns FR2a and FR2b of word lines WL2a and WL2b project toward the relatively wide second space L2 taken in the X direction.

Further, fringe patterns FR1b and FR2a of the opposing paired word-lines, spaced apart by second space L2, are spaced from one another in the X direction by third space L3. The fringe patterns FR of each pair are not displaced from each other in the Y direction.

FIGS. 12C and 12D are vertical cross-sectional views of the portions taken along lines 12C-12C and 12D-12D of FIG. 12B. In FIG. 12C, both of word lines WL1a and WL1b of paired word-lines PWL1 and both of word lines WL2a and WL2b of paired word-lines PWL2 are bent in the Y direction in hook-up region B. Word lines WL1a and WL1b of paired word-lines PWL1 each has first width D1 and are spaced from one another in the X direction by first space L1. Similarly, word lines WL2a and WL2b of paired word-lines PWL2 each has first width D1 and are spaced from one another in the X direction by first space L1. Paired word-lines PWL1 and PWL2 are spaced from one another in the X direction by second space L2. In FIG. 12D, fringe patterns FR1a and FR1b are formed to word lines WL1a and WL1b, respectively and fringe patterns FR2a and FR2b are formed to word lines WL2a and WL2b, respectively.

By adopting the above described structure, it is possible to dispose fringe patterns FR (FR1a to FR2b) of word lines WL (WL1a to WL2b) in hook-up region B of word lines WL efficiently and in smaller spaces.

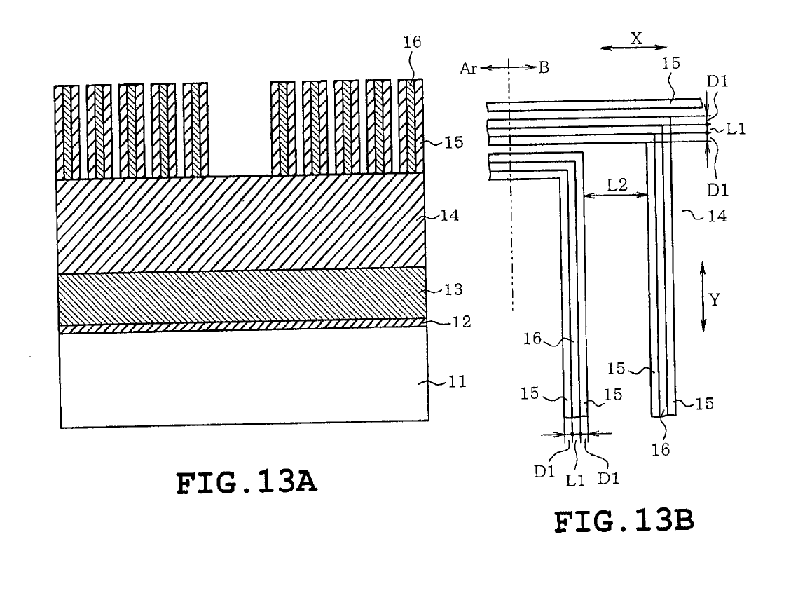

Next, a description will be given on the manufacturing process flow of the above described structure with reference to FIGS. 13A to 19B.

The structures illustrated in FIGS. 13A and 13B are formed of gate insulating film 12, gate electrode film 13, and insulating film 14 stacked above semiconductor substrate 1. Mandrel patterns 16 having sidewall patterns 15 formed along both side surfaces are formed above the stacked films. Gate electrode film 13 is a stacked film for forming gate electrodes MG of memory-cell transistors and gate electrodes SG of select transistors and is similar in structure to gate electrode film 3 of the first embodiment. Further, gate electrode film 13 constitutes a portion of word lines WL1a, WL1b, WL2a, WL2b . . . and a portion of patterns extending into hook-up region B.

Each of insulating film 14, sidewall pattern 15, and mandrel pattern 16 are made of different materials. Thus, it is possible to selectively etch the foregoing films by RIE (reactive ion etching) or a wet process. For example, a silicon oxide film, a silicon nitride film, and a silicon film (polycrystalline silicon film or amorphous silicon film) may be used uniquely as insulating film 14, sidewall pattern 15, and mandrel pattern 16. As a result, it is possible to etch the foregoing films independently and selectively.

Mandrel patterns 16 are formed as line-and-space patterns having a line width and a space width which are each approximately twice the size of first width D1. The line width of mandrel patterns 16 is thereafter reduced to first width D1 by a slimming process. Mandrel patterns 16 are spaced from one another by a space width which is approximately 3 times of first width D1. Two sidewall patterns 15 form a pair and serves as a paired wiring mask. The paired wiring masks are shaped like spacers and are formed by forming a conformal film extending along insulating film 14 and along the side surfaces and upper surfaces of mandrel patterns 16 and etching back the conformal film by RIE or the like. Each sidewall pattern 15 has first width D1. Paired wiring masks PAM1, PAM2, . . . correspond to paired word-lines PWL1, PWL2, . . . , respectively.

Sidewall patterns 15 serve as masks for forming gate electrodes MG of memory-cell transistors MT and word lines WL. Masks are not formed in portions corresponding to gate electrodes SG of select transistors STD and STS disposed adjacent to one another and thus, such portions remain exposed.

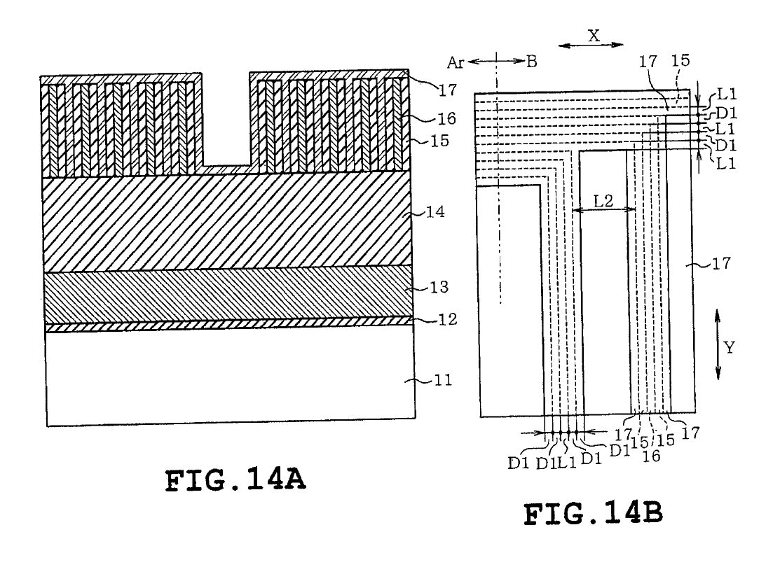

Then, as shown in FIGS. 14A and 14B, processing film 17 serving as a fourth processing film is deposited. Processing film 17 is made of a material identical to the material of mandrel pattern 16 or a material having a wet etching rate similar to the wet etching rate of mandrel pattern 16. As a result, processing film 17 is formed above the surfaces of sidewall patterns 15 and mandrel patterns 16 and is filled in the gaps between sidewall patterns 15 in the memory-cell region. Further, processing film 17 is formed conformally along the side surfaces of sidewall patterns 15 and the upper surface insulating film 14 in the regions where gate electrodes SG are to be formed. In hook-up region B, processing film 17 is formed conformally along the upper surfaces and side surfaces of paired wiring masks PAM and between paired wiring masks spaced from one another by second space L2.

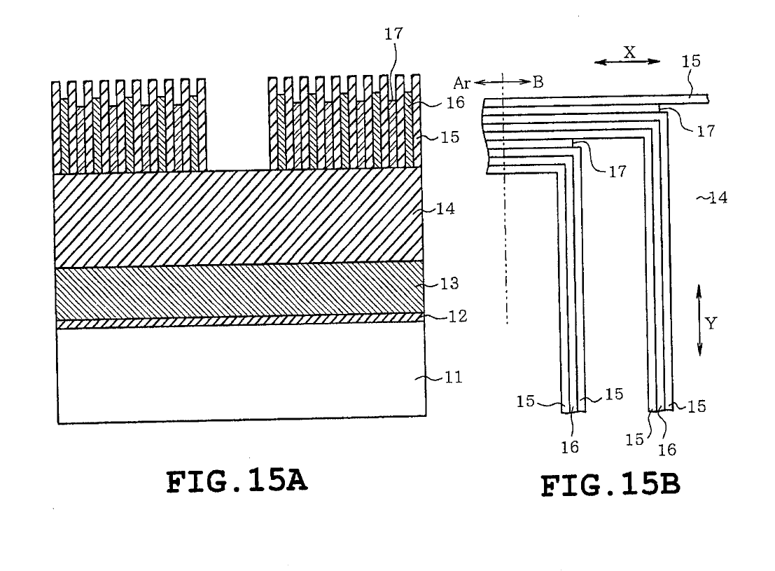

Then as shown in FIGS. 15A and 15B, processing film 17 is etched isotropically by wet etching or dry etching. Processing film 17 and mandrel patterns 16 are etched isotropically in a substantially similar manner. The etching removes processing films 17 located above the upper surface portions of sidewall patterns 15 and mandrel patterns 16 and processing films 17 located in the regions wider than space D1. On the other hand, most of mandrel patterns 16 and processing films 17 located between sidewall patterns 15 remain, though they are etched to heights slightly below the upper surfaces of sidewall patterns 15. Thus, as shown in FIG. 15B, processing films 17 remain so as to be terminated at the portions in hook-up region B in which paired word-lines PWL are bent in the Y direction which may be described, for example, as portions where there are wide spaces between paired word-lines PWL. On the other hand, mandrel pattern 16 remains between the two word lines WLa and WLb of paired word-lines PWL in hook-up region B.

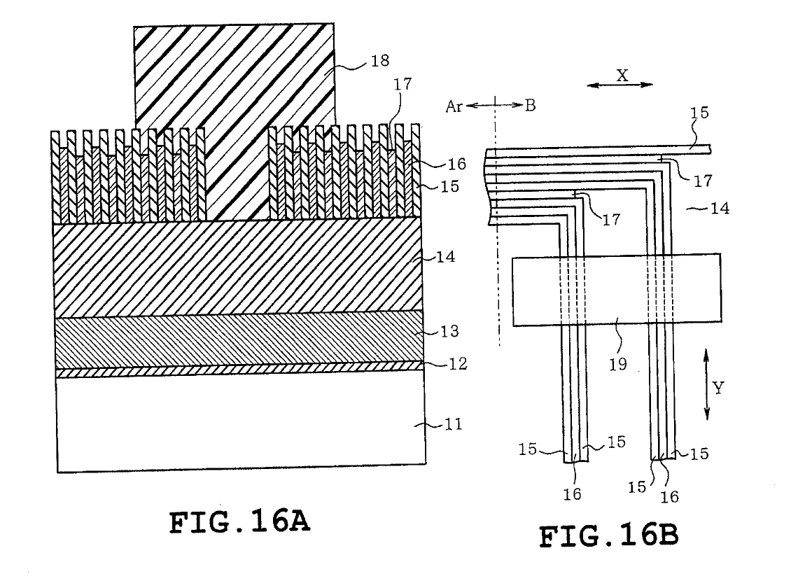

Then, as shown in FIGS. 16A and 16B, a resist film is formed and patterned to form resist masks 18 and 19. Resist mask 18 is patterned to cover the portion of the memory-cell region corresponding to gate electrodes SG of select transistors. As shown in FIG. 16A, resist mask 18 covers the region where the gap between sidewall patterns 15 is wide and further covers several sidewall patterns located on both sides of the gap. Further, as shown in FIG. 16B, resist mask 19 is formed so as to extend in the X direction across at least two paired wiring masks PAM located in hook-up region B.

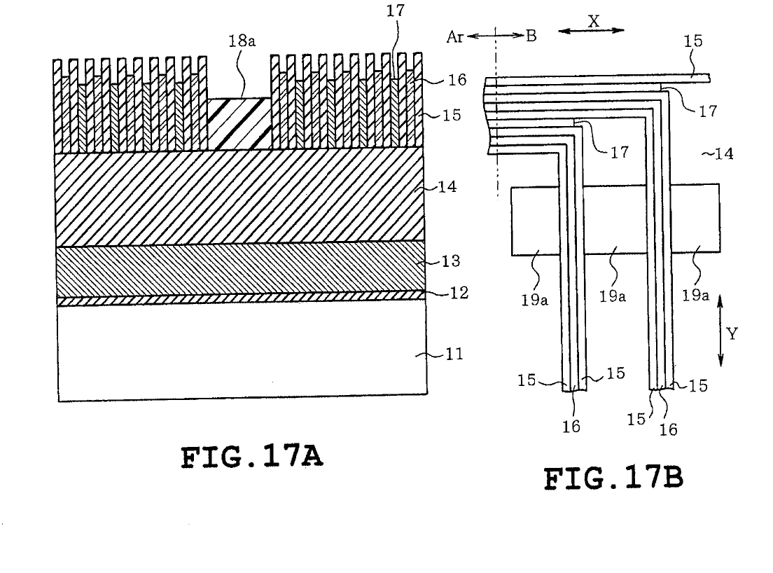

Then, as shown in FIGS. 17A and 17B, the heights of resist masks 18 and 19 are lowered so as to be below the upper surfaces of mandrel patterns 16. The heights of resist masks 18 and 19 may be lowered for example by selectively etching the resist masks 18 and 19 by RIE. As a result, portions of resist masks 18 and 19 located above sidewall patterns 15, mandrel patterns 16, and processing films 17 are removed. Resist mask 18 remains in portion 18a between sidewall patterns 15 in which gate electrodes of select transistors are to be formed. Further, portions of resist mask 19 located above the upper portions of sidewall patterns 15 and mandrel patterns 16 in hook-up region B are removed, and portions 19a of resist mask 19 located between paired wiring masks PAM in the X direction remain as shown in FIG. 17B.

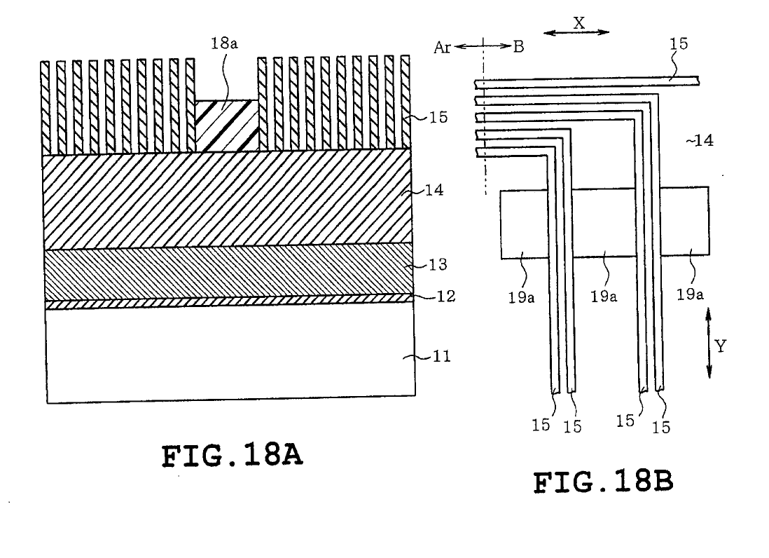

Then, as shown in FIGS. 18A and 18B, mandrel patterns 16 and processing films 17 are selectively removed by wet etching. As a result, mandrel patterns 16 and processing films 17 filled in the gaps between sidewall patterns 15 are removed and sidewall patterns 15 and resist masks 18a and 19a remain above insulating film 14.

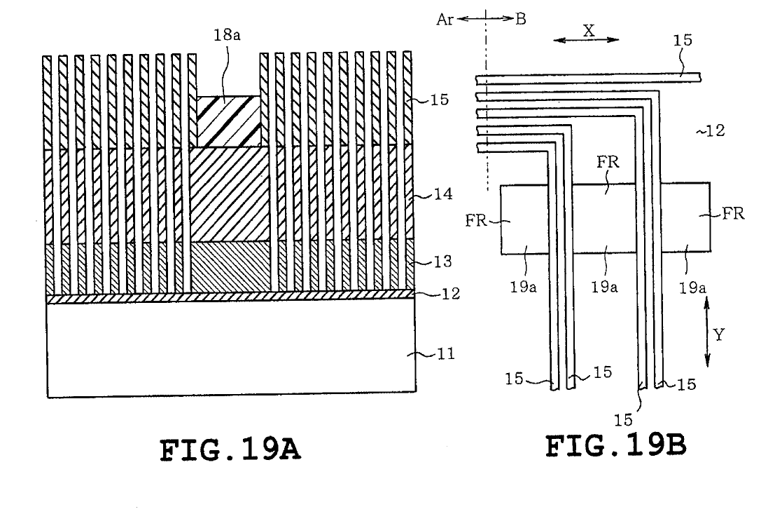

Then, as shown in FIGS. 19A and 19B, insulating film 14 and gate electrode film 13 are processed by RIE using sidewall patterns 15 and resist masks 18a and 19a as masks. As a result, gate electrodes MG of memory-cell transistors are formed from gate electrode films 13 in the memory-cell region. At this phase of the manufacturing process flow, gate electrode film 13 corresponding to opposing gate electrodes SG of select transistors STD and STS are not divided as shown in FIG. 19A. In hook-up region B, word lines WL formed from gate electrode films 13 and interlinked fringe patterns FR are formed as shown in FIG. 19B.

Then, as shown in FIGS. 12A to 12D, sidewall patterns 15, resist masks 18a and 19a, and insulating films 14 are removed. Then, a lithographic patterning is carried out to divide the wide portions of gate electrode films 13 formed by resist masks 18a and 19a in the memory-cell region and in hook-up region B. Gate electrodes SG of two select transistors are formed in the memory-cell region.

When processing gate electrodes SG of these select transistors, interlined fringe patterns FR are divided at the X-direction central portion at the same time. The dividing of fringe patterns FR is carried out by forming openings Ca having third space L3 in the X direction with resist patterns by photolithography. Then, gate electrode films 13 exposed by openings Ca are removed by RIE. Thus, divided fringe patterns FR1a, FR1b, FR2a, and FR2b are formed as shown in FIG. 12B. As a result, it is possible to simplify the manufacturing process flow.

In the second embodiment, it is possible to form fringe patterns FR in hook-up region B of word lines WL without an additional lithography step as was the case in the first embodiment. Further, it is possible to configure the spaces between gate electrodes SG of select transistors ST and gate electrodes MG of the adjacent memory-cell transistors M to be substantially equal to the spaces between adjacent gate electrodes MG. As a result, it is possible to inhibit gauging of the semiconductor substrate located between gate electrodes MG of memory-cell transistors MT.

Further, in the step illustrated in FIG. 16, resist mask 19 can be formed substantially in a straight line. As a result, it is possible to dispose fringe patterns FR1a, FR1b, FR2a, and FR2b consecutively in the X direction. Thus, it is possible to reduce the Y-direction width of hook-up region.

### Modified Example of Second Embodiment

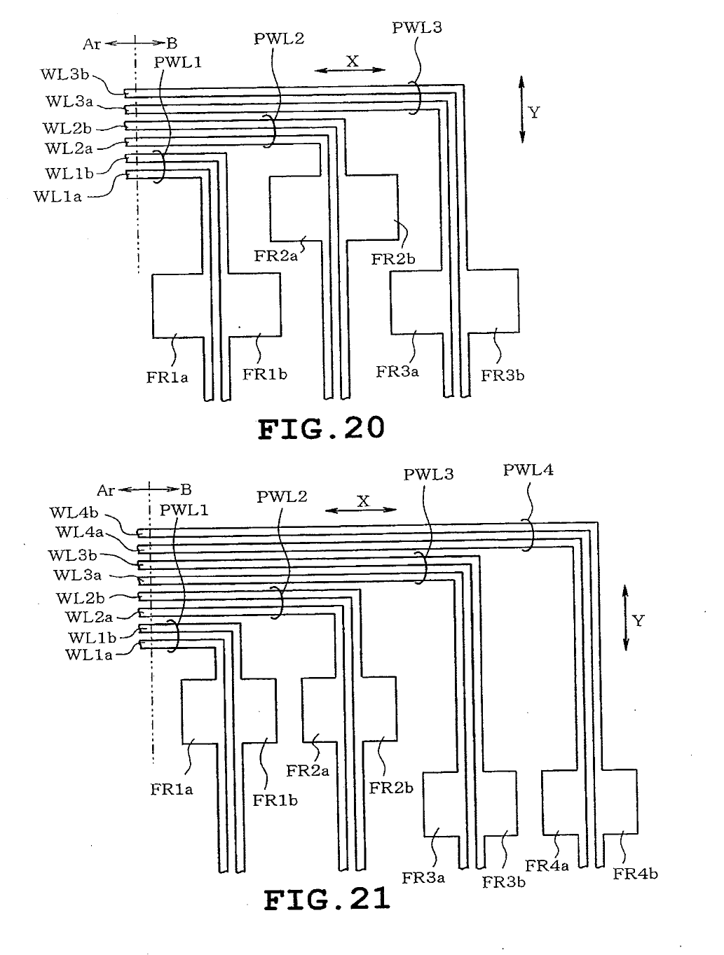

FIGS. 20 and 21 are modified examples in which the layout of fringe patterns FR formed in the second embodiment is modified. In the example illustrated in FIG. 20, fringe patterns FR1a and FR1b are provided for word lines WL1a and WL1b of paired word-lines PWL1 and fringe patterns FR2a and FR2b are provided for word lines WL2a and WL2b of paired word-lines PWL2. Fringe patterns FR2a and FR2b are displaced in the Y direction from fringe patterns FR1a and FR1b. On the other hand, fringe patterns FR3a and FR3b for word lines WL3a and WL3b of paired word-lines PWL3 are disposed in the same Y-direction position as fringe patterns FR1a and FR1b. Thus, a zigzag layout is adopted in which the adjacent fringe patterns being paired are displaced from one another in the Y direction.

It is further possible to arrange fringe pattern FR1b and fringe pattern FR2a to partially overlap in the X direction. As a result, it is possible to reduce the X-direction width of hook-up region B.

In the example shown in FIG. 21, the layout of the two pairs of fringe patterns FR1a, FR1b and FR2a, FR2b formed in the second embodiment is arranged so as to be displaced in the Y direction from the adjacent two pairs of fringe patterns FR. More specifically, the group of fringe patterns FR1a, FR1b, FR2a, and FR2b illustrated in FIG. 12B is displaced in the Y direction from the adjacent group of fringe patterns FR3a, FR3b, FR4a, and FR4b of paired word-lines PWL3 and PWL4 to provide a zigzag layout.

It is possible to obtain the operation and effect similar to those of the first embodiment by the layouts illustrated in FIGS. 20 and 21.

### Third Embodiment

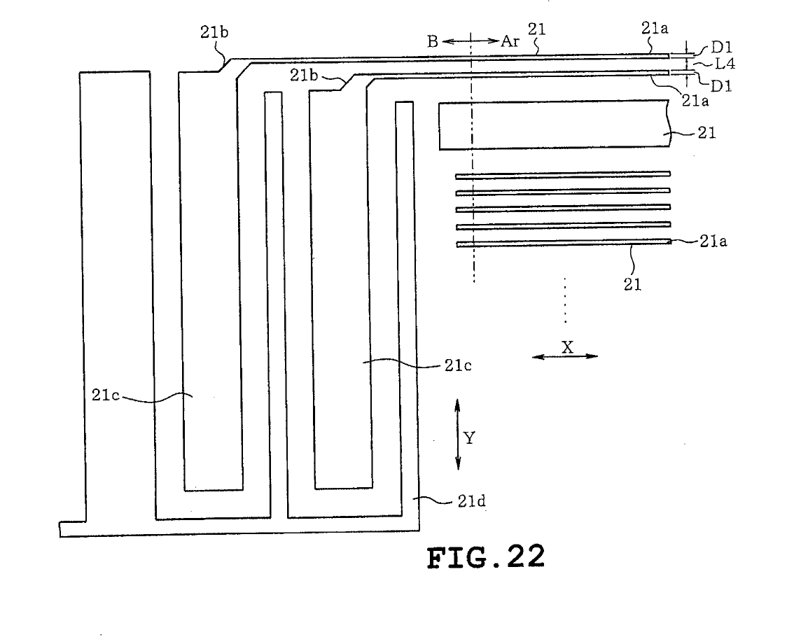

FIGS. 22 to 25 illustrate a third embodiment. The third embodiment differs from the foregoing embodiments in that dummy patterns are provided in hook-up regions B during the manufacturing process flow. Dummy patterns are provided to ensure proper formation of wiring patterns which are formed by sidewall transfer technique. Dummy patterns are patterns which are not used as circuit elements.

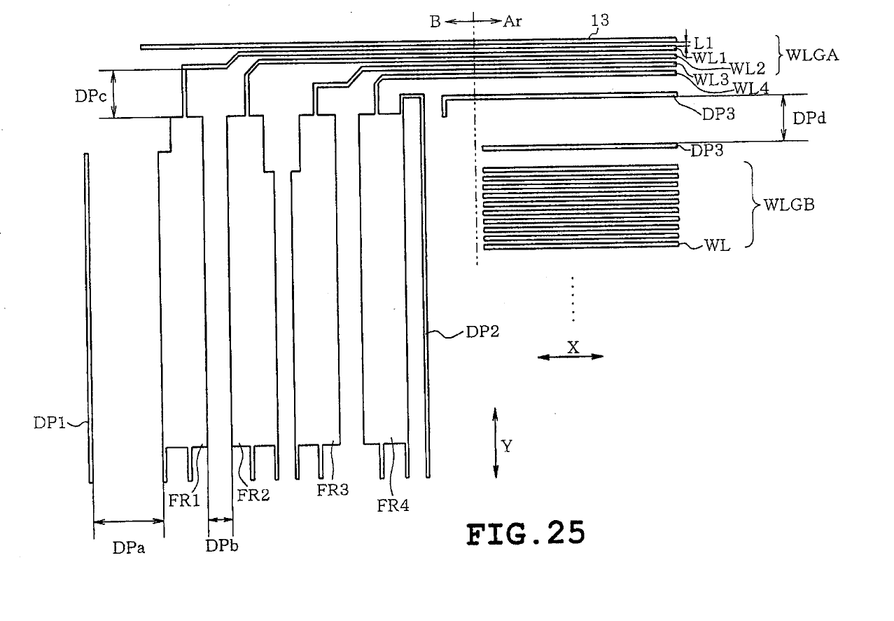

FIG. 25 is one example of a plan view of hook-up region B of word lines and fringe patterns formed by sidewall transfer technique. As shown in FIG. 25, word lines WL1 to WL4 formed by processing gate electrode film 13 for example extend in the X direction as was the case in the first and the second embodiments. Word lines WL1 to WL4 each has first width D1 and are spaced from one another in the Y direction by first space L1. Word lines WL1 to WL4 are grouped as word-line group WLGA.

Word lines WL1 to WL4 are bent in the Y direction in hook-up region B. Fringe patterns FR1 to FR4 for forming contacts are provided for each of word lines WL1 to WL4 in hook-up region B. Other word lines WL not shown also extend into hook-up region B and are bent in the Y direction. Fringe patterns FR are provided to such word lines WL as well. Fringe pattern FR1 is disposed so as to be the farthest in the X direction from the boundary of memory-cell array region Ar and hook-up region B. Fringe patterns FR2, FR3, and FR4 become closer to word-line group WLGA in the listed sequence.

Fringe patterns FR1 to FR4 are arranged to be spaced from one another adjacent in the X-direction by a predetermined space (200 nm for example) or less. For each of fringe patterns FR1 to FR4, when a fringe pattern adjacent in the X direction does not exist or is remote, dummy patterns DP1 and DP2 are formed for example so that the space between the fringe patterns adjacent in the X direction is equal to or less than the predetermined distance (200 nm for example). Dummy patterns DP3 are disposed between word-line group WLGA and word-line group WLGB spaced from word-line group WLGA in the Y direction. The fringe patterns of word lines WL belonging to word-line group WLGB are disposed at the ends of word lines WL located in the opposite side of hook-up region B in the X direction. Dummy patterns DP3 are formed by cutting a portion of a loop shaped pattern. Wirings project downward from the Y-direction lower sides of fringe patterns FR1 to FR4. The projecting wirings are parts of word lines WL or dummy patterns.

Referring to FIG. 25, distance DPa between dummy pattern DP1 and fringe pattern FR1 is equal to or less than 200 nm and is greater than distance DPb between fringe patterns FR. Further, distance DPc between word lines WL and fringe patterns FR is less than distance DPa in hook-up region B. In other words, the lengths of word lines WL extending in the Y direction are less than distance DPa in hook-up region B. Further, distance DPd between dummy patterns DP3 adjacent in the Y direction is less than distance DPa.

Next, a description will be given on a manufacturing process flow of the above described structures with reference to FIGS. 22 to 25.

First, as shown in FIG. 22, mandrel patterns 21 are formed. As was the case in the second embodiment, gate insulating film 12 and gate electrode film 13 are formed above semiconductor substrate 11. Gate electrode film 13 is processed to form gate electrodes or word lines WL. Insulating film 14 serving as a processing film is formed above gate electrode film 13 and an insulating film for forming mandrel patterns are formed above the upper surface of insulating film 14. The insulating film is patterned as shown in FIG. 22 to obtain mandrel patterns 21.

Mandrel patterns 21 are configured by sub portions, namely, mandrel patterns 21a, mandrel patterns 21b, and mandrel patterns 21c. Mandrel patterns 21a correspond to word lines WL extending in the X direction. Mandrel patterns 21b located in hook-up region B correspond to the portions being bent in the Y direction. Mandrel patterns 21c located in hook-up region B are expanded in the X direction to form fringe patterns. Further, in mandrel patterns 21a corresponding to word lines WL, fourth space L4 is provided which is 3 times the width of first width D1 (=3×D1). In mandrel patterns 21c forming the fringe patterns, space L2 between the adjacent patterns 21c is configured for example to be greater than 200 nm.

Dummy mandrel patterns 21d are formed between mandrel patterns 21c adjacent in the X direction. Dummy mandrel patterns 21d are interlinked in one and are disposed so as to surround mandrel patterns 21c corresponding to fringe patterns of mandrel patterns 21 from three sides. As a result, mandrel patterns 21c corresponding to fringe patterns FR of mandrel patterns 21 are spaced from dummy mandrel patterns 21d by a predetermined space (200 nm for example) or less.

Further, mandrel patterns 21a of mandrel patterns 21 corresponding to word lines WL are formed as line-and-space patterns in which the line width and the space width are substantially equal. Mandrel patterns 21a, after being patterned, are subjected to a slimming process to reduce the line width to first width D1 which is approximately half of the original width. Mandrel patterns 21a are disposed so as to be spaced from one another in the Y direction by fourth space L4 (three times the width of first width D1).

In the above described pattern layout, the films serving as mandrels are processed by RIE to form mandrel patterns 21a to 21c and dummy mandrel patterns 21d. Thus, it is possible to form mandrel patterns 21a to 21c having steep side surfaces (large taper angles), in other words, substantially upright side surfaces.

When forming mandrel patterns 21a to 21c, it may not be possible to form steep side surfaces (resulting in small taper angles) when there is large distance between the adjacent patterns. It may also not be possible to form steep side surfaces depending upon the anisotropic etching conditions applied during RIE. When the contact angles of the side surfaces of mandrel patterns 21a to 21c are small, the contact angles of sidewall patterns 22a to 22c formed along the side surfaces of mandrel patterns 21a to 21c also become small. This may influence the subsequent processes. In this respect, the third embodiment forms dummy mandrel patterns 21d when forming mandrel patterns 21a to 21c so that the distance between the adjacent patterns are equal to or less than a predetermined distance. As a result, it is possible to increase the contact angles (increase the taper angles) of the side surfaces of mandrel patterns 21a to 21c so as to be substantially upright.

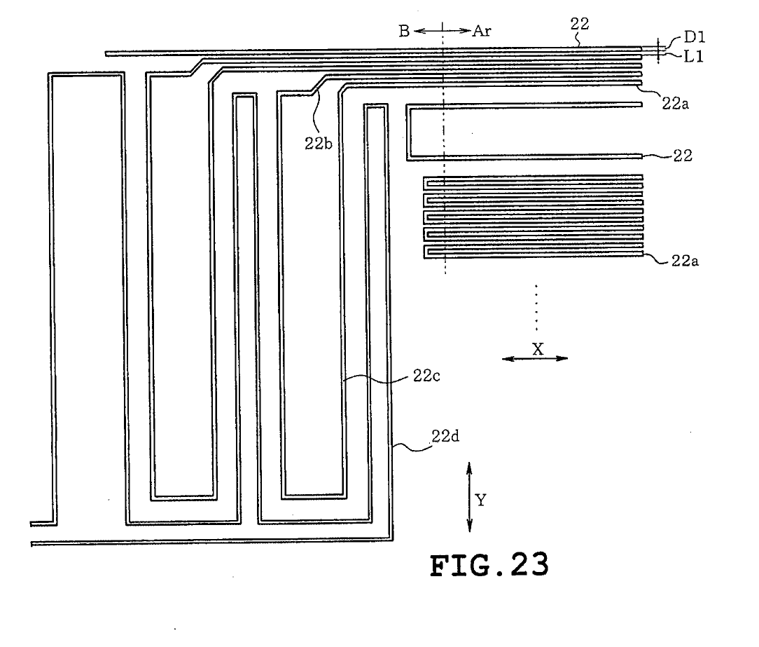

Next, as shown in FIG. 23, sidewall patterns 22a to 22c and dummy sidewall pattern 22d are formed using mandrel patterns 31a to 21c and dummy mandrel pattern 21d. A description will be given on the manufacturing process flow for forming sidewall patterns 22a to 22c and dummy sidewall pattern 22d. First, a processing film having a thickness D1 for forming sidewall patterns is formed along the upper surfaces and side surfaces of mandrel patterns 21a to 21c and dummy mandrel pattern 21d and above an insulating film. Then, the processing film is etched back by RIE so as to remain in the shapes of spacers along the side surfaces of mandrel patterns 21a to 21c and dummy mandrel pattern 21d to thereby form sidewall patterns 22a to 22c and dummy sidewall pattern 22d. Thereafter, mandrel patterns 21a to 21c and dummy mandrel pattern 21d are selectively removed.

As described earlier, mandrel patterns 21a to 21c have steep side surfaces (large taper angles), in other words, substantially upright side surfaces. Sidewall patterns 22a to 22c and dummy sidewall pattern 22d are formed in the shape of a loop so as to surround mandrel patterns 21a to 21c and dummy mandrel pattern 21d.

Among sidewall patterns 22, sidewall patterns 22a extending in the X direction which is the direction in which word lines WL are formed have first width D1. Sidewall patterns 22a are spaced from one another by first space L1 which is equal to first width D1. Sidewall patterns 22b which are bent in the Y direction of hook-up region B and sidewall patterns 22c corresponding to the fringe patterns have first width D1 and are formed in the shape of a loop so as to surround mandrel patterns 21b and 21c. Similarly, dummy sidewall patterns 22d having first width D1 are formed in a shape of a loop so as to surround dummy mandrel pattern 21d.

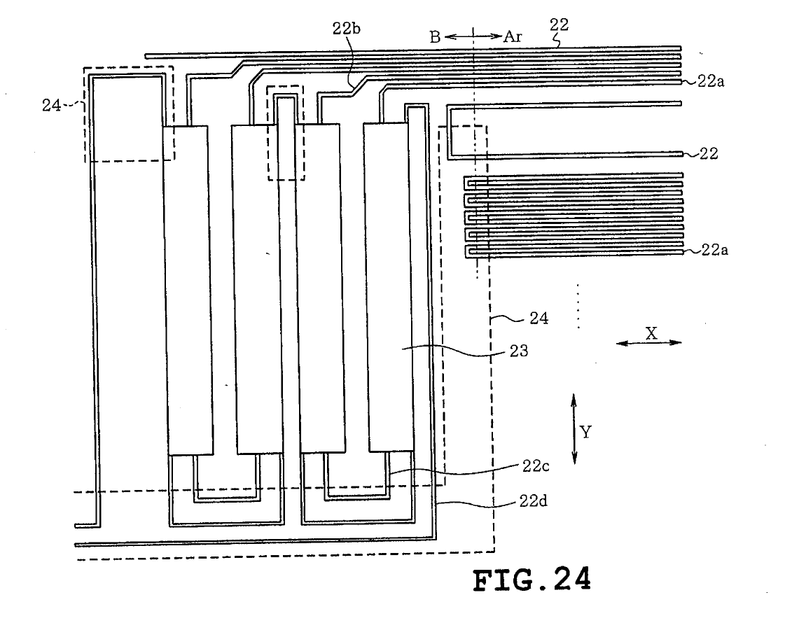

Next, resist patterns 23 for forming fringe patterns are formed by lithography. As shown in FIG. 24, resist patterns 23 are formed above the two longer sides of sidewall patterns 22c shaped like loops. Further, resist patterns 23 are formed so as to extend above dummy sidewall patterns 22d adjacent in the X direction. It is possible to form resist patterns 23 above sidewall pattern 22 disposed between word-line group WLGA and word-line group WLGB. The widths of resist patterns 23 are greater than the widths of sidewall patterns.

Then, as shown in FIG. 25, the insulating films and gate electrode films in the lower layers are processed by RIE using sidewall patterns 22a to 22c, dummy sidewall patterns 22d, and resist patterns 23 as masks. As a result, word lines WL1 to WL 4, fringe patterns FR1 to FR4, and dummy patterns DP1 to DP3 are formed. As described earlier, sidewall patterns 22a to 22c and dummy sidewall patterns 22d are formed so as to be substantially upright with respect to the surface of the substrate. As a result, sidewall patterns 22a to 22c serve sufficiently as masks for anisotropic etching when processing the insulating films and gate electrode films. It is thus, possible to perform reliable patterning.

Then, sidewall patterns 22a to 22c, dummy sidewall patterns 22d, and resist patterns 23 are removed. Further, resist patterns are formed so as to form openings in regions 24 indicated by broken lines in FIG. 24. More specifically, regions 24 form openings in the looped portions of word lines WL extending from each of fringe patterns FR. Next, gate electrode films located in regions 24 are removed using the resist patterns as masks. As a result, portions of word lines WL, fringe patterns FR, and dummy patterns DP1 to DP3 connected in the form of loops are cut and each fringe pattern FR becomes electrically independent.

In the third embodiment, dummy mandrel patterns 21d are disposed in portions where mandrel patterns 21a to 21c adjacent in the X direction are spaced from one another by a distance greater than a predetermined distance (200 nm for example) when forming sidewall patterns 22 serving as processing masks. As a result, it is possible to form substantially upright sidewall patterns 22a to 22c. Sidewall patterns 22a to 22c are processed so as to serve as masks used in RIE. Thus, it is possible to reliably process insulating films and gate electrode films 13 without causing disconnections.

### Fourth Embodiment

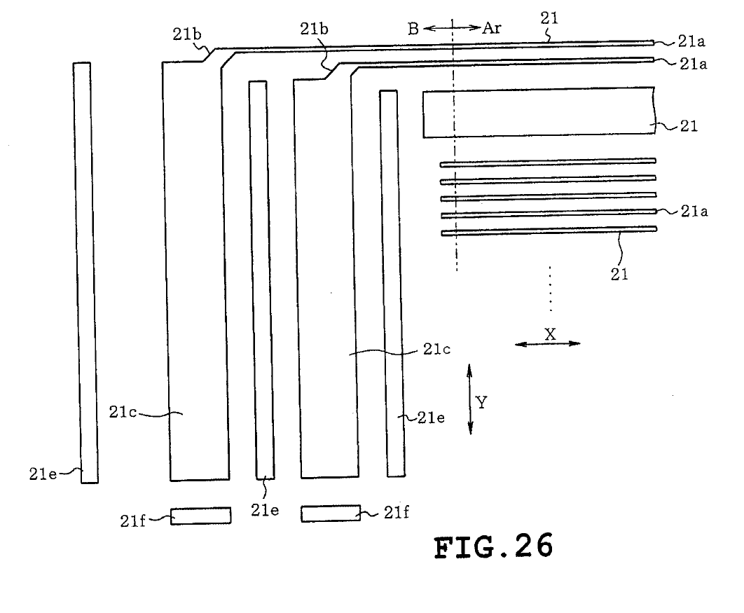

FIGS. 26 to 29 illustrate a fourth embodiment. Description will be given hereinunder on the differences from the foregoing embodiments.

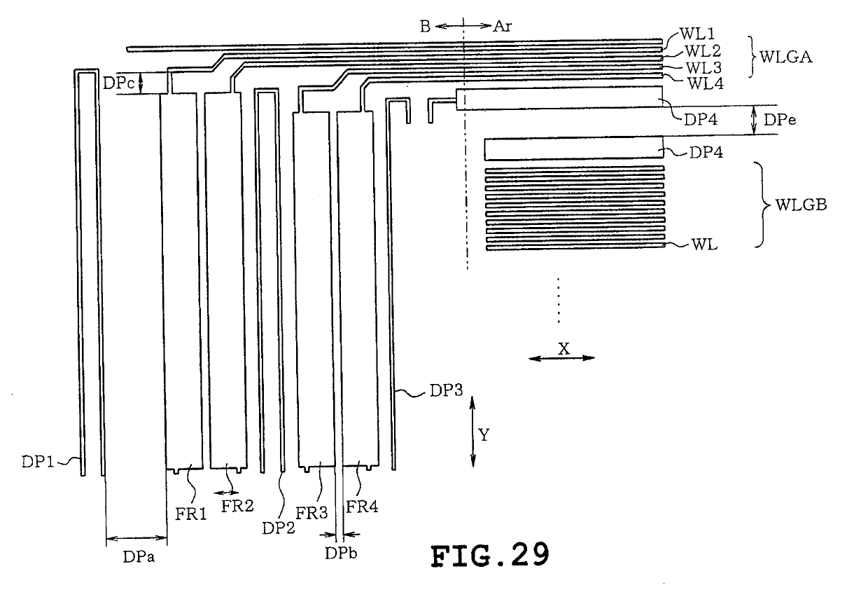

FIG. 29 is one example of a plan view of hook-up region B of word lines WL and fringe patterns FR formed by sidewall transfer technique. For example, word lines WL1 to WL4 and fringe patterns FR1 to FR4 obtained by processing gate electrode film 13 are formed as was the case in the third embodiment. In the third embodiment, the X-direction widths of fringe patterns FR1 to FR4 are smaller than those of the third embodiment. Thus, fringe patterns FR1 to FR4 do not overlap with dummy patterns DP1 to DP3. A single wiring projects downward from the Y-direction lower side of each of fringe patterns FR1 to FR4. The projecting wirings are parts of word lines WL. Dummy patterns DP4 are disposed between word-line group WLGA and word-line group WLGB spaced from word-line group WLGA in the Y direction. Dummy fringe patterns are formed for dummy patterns DP4. Dummy fringe patterns have thicknesses greater than the thicknesses of word lines WL and extend in the X direction.

Distance DPa between dummy pattern DP1 and fringe pattern FR1 is equal to or less than 200 nm as described earlier and is greater than distance DPb between fringe patterns FR. Further, distance DPc between word lines WL and fringe patterns FR is less than distance DPa in hook-up region B. In other words, the lengths of word lines WL extending in the Y direction are less than distance DPa in hook-up region B. Further, distance DPe between dummy patterns DP4 adjacent in the Y direction is less than distance DPa.

Next, a description will be given on a manufacturing process flow of the above described structures with reference to FIGS. 26 to 29.

As shown in FIG. 26, mandrel patterns 21 are formed above the insulating film. Gate insulating film and gate electrode film 13 are formed above the semiconductor substrate. An insulating film serving as a processing film is formed above gate electrode film 13. Further, an insulating film for forming mandrel patterns 21 are formed above the processing film and the insulating film is patterned by lithography techniques such as RIE to obtain mandrel patterns 21.

Mandrel patterns 21 are configured by mandrel patterns 21a, 21b, and 21c. Mandrel patterns 21a correspond to word lines WL extending in the X direction. Mandrel patterns 21b located in hook-up region B correspond to the portions being bent in the Y direction. Mandrel patterns 21c located in hook-up region B are expanded to form fringe patterns. Long and rectangular dummy mandrel patterns 21e are formed between adjacent mandrel patterns 21c. Rectangular dummy mandrel patterns 21f are formed so as to face the end portions of dummy mandrel patterns 21e. Thus, dummy mandrel patterns 21e and 21f surround mandrel patterns 21c from three sides. As a result, mandrel patterns 21c are spaced from dummy mandrel patterns 21d by a predetermined space (200 nm for example) or less.

As described above, the films serving as mandrels are processed to form mandrel patterns 21a to 21c and dummy mandrel patterns 21e and 21f. Thus, it is possible to form mandrel patterns 21a to 21c having steep side surfaces (large taper angles), in other words, substantially upright side surfaces.

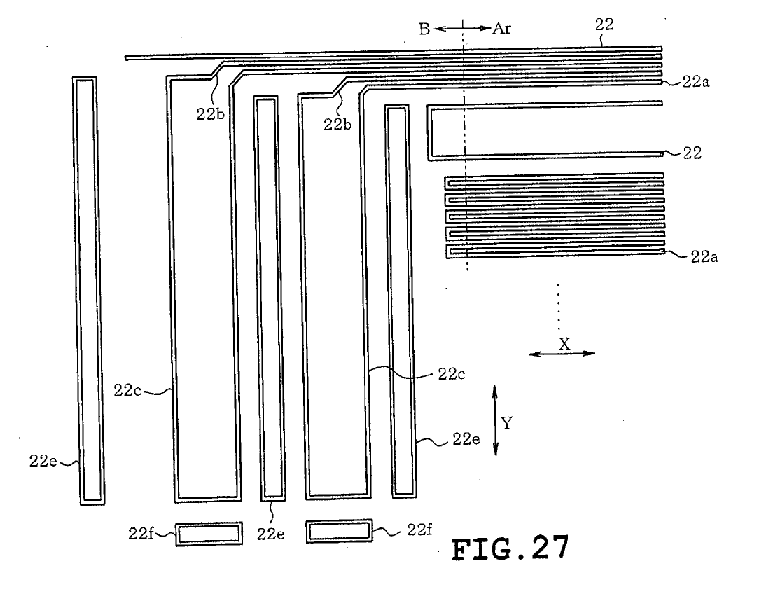

Next, a processing film for forming sidewall patterns is formed above mandrel patterns 21a to 21c and dummy mandrel patterns 21e and 21f. Then, the processing film is etched back to form sidewall patterns 22 as shown in FIG. 27. As described earlier, mandrel patterns 21a to 21c are formed to have steep side surfaces (large taper angles), in other words, substantially upright side surfaces. Thus, it is possible to form sidewall patterns 22a to 22c disposed along the side surfaces to be substantially upright (large taper angles) with respect to the surface of the substrate. Sidewall patterns 22a to 22c and dummy sidewall patterns 22e and 22f are formed in the shape of a loop so as to surround mandrel patterns 21a to 21c and dummy mandrel pattern 21e and 21f.

Among sidewall patterns 22, sidewall patterns 22a extending in the X direction which is the direction in which word lines WL are formed have first width D1. Sidewall patterns 22a are spaced from one another by first space L1 which is equal to first width D1. Sidewall patterns 22b which are bent in the Y direction of hook-up region B and sidewall patterns 22c corresponding to the fringe patterns have first width D1 and are formed in the shape of a loop so as to surround mandrel patterns 21b and 21c. Similarly, dummy sidewall patterns 22e and 22f having first width D1 are formed in the shape of a loop so as to surround dummy mandrel patterns 21e and 21f.

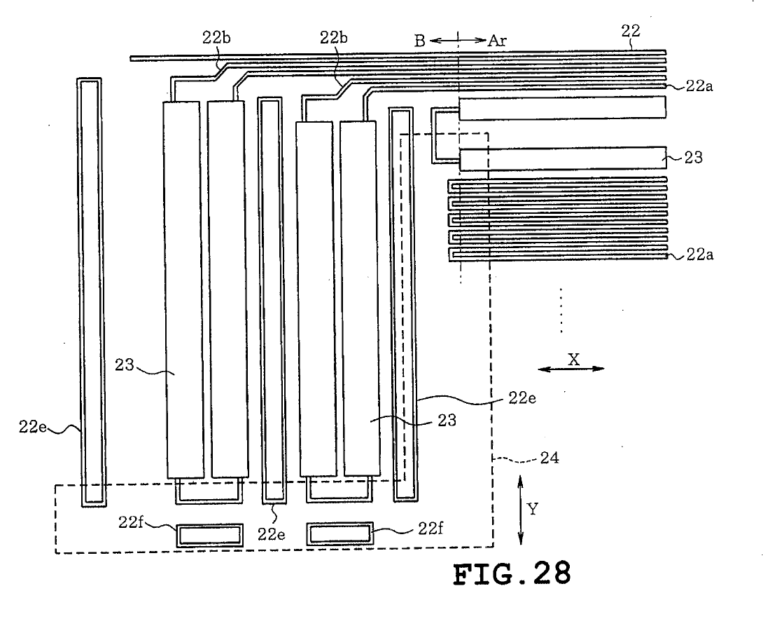

Next, resist patterns 23 for forming fringe patterns are formed by lithography. As shown in FIG. 28, resist patterns 23 are formed above the two longer sides of sidewall patterns 22c shaped like loops. Resist patterns 23 are formed so as to be spaced from dummy sidewall patterns 22e adjacent in the X direction. The distances between resist patterns 23 and adjacent dummy sidewall patterns 22e and the distances between adjacent resist patterns 23 are less than 200 nm.

Then, as shown in FIG. 29, the insulating films and gate electrode films in the lower layers are processed by RIE using sidewall patterns 22a to 22c, dummy sidewall patterns 22e and 22f, and resist patterns 23 as masks. As a result, word lines WL1 to WL 4, fringe patterns FR1 to FR4, and dummy patterns DP1 to DP4 are formed. As described earlier, sidewall patterns 22a to 22c and dummy sidewall patterns 22e and 22f are formed so as to be substantially upright. As a result, sidewall patterns 22a to 22c serve sufficiently as masks for anisotropic etching when processing the insulating films and gate electrode films. It is thus, possible to prevent partial dissipation of word lines WL.

Then, sidewall patterns 22a to 22c, dummy sidewall patterns 22e and 22f, and resist patterns 23 are removed so as to form openings in regions 24 indicated by broken lines in FIG. 28. More specifically, regions 24 form openings in the looped portions of word lines WL extending from each of fringe patterns FR. Next, gate electrode films located in regions 24 are removed using the resist patterns as masks. As a result, portions of word lines WL, fringe patterns FR, and dummy patterns DP1 to DP4 connected in the form of loops are cut and each fringe pattern FR becomes electrically independent.

It is possible to obtain the operation and effect similar to those of the third embodiment in the fourth embodiment. The shapes and layouts of structures such as dummy patterns DP1 to DP4 may be modified as long as the spaces from adjacent mandrel patterns are equal to or less than a predetermined spacing.

### Fifth Embodiment

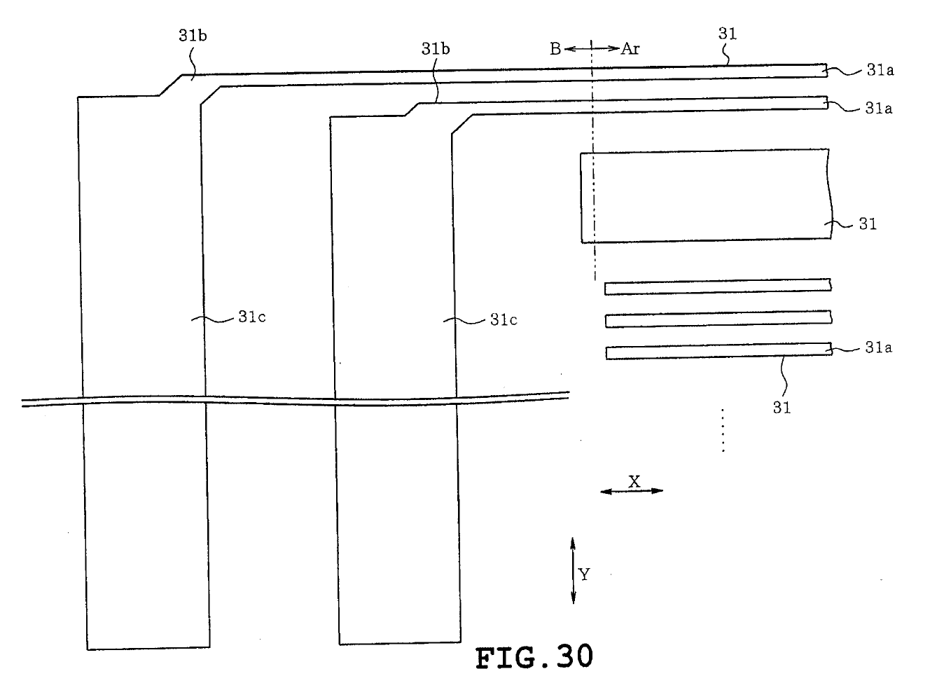

FIGS. 30 to 35 illustrate a fifth embodiment. Description will be given hereinunder based primarily on the differences from the third embodiment. In the fifth embodiment, smaller word lines WL and wiring patterns are formed by performing the sidewall transfer technique twice. Dummy patterns are formed in the second sidewall transfer step.

In the fifth embodiment, dummy patterns are disposed when the sidewall transfer technique is used for the second time. This is based on an assumption that, it is possible to form the side surfaces of the patterns to be substantially upright with respect to the substrate without using the dummy patterns when the sidewall transfer technique is used for the first time.

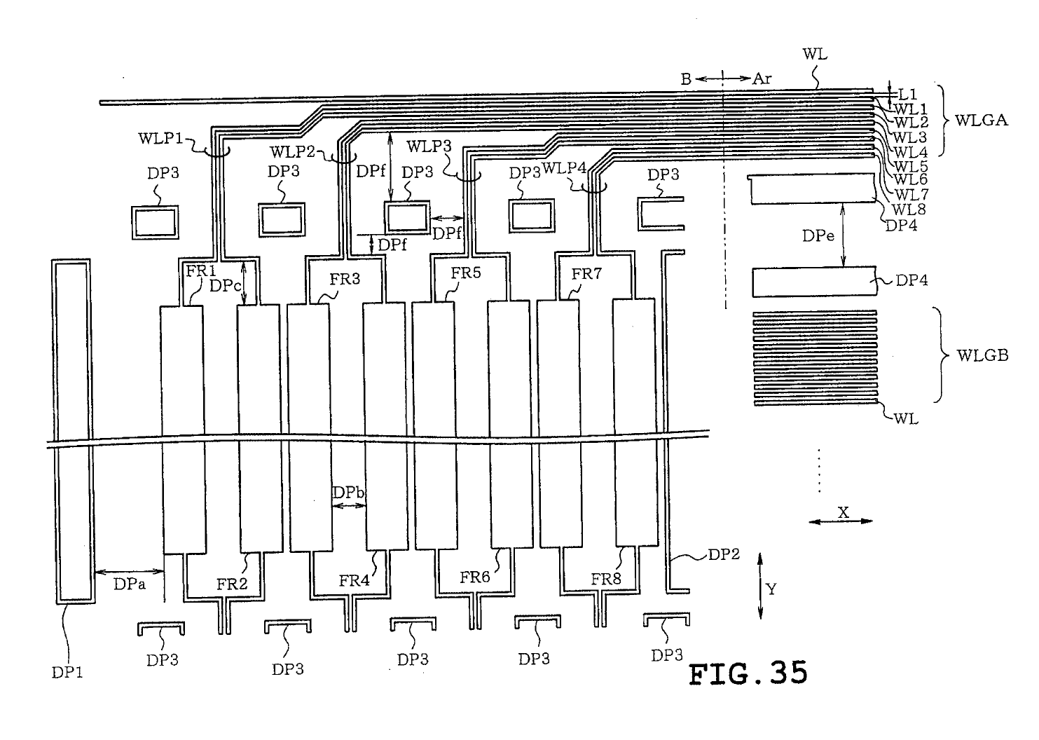

FIG. 35 is one example of a plan view of hook-up region B of word lines WL and fringe patterns FR formed by sidewall transfer technique performed twice. For example, word lines WL1 to WL8 obtained by processing gate electrode film 13 extend in the X direction as was the case in the second embodiment. Word lines WL1 to WL8 are disposed with a predetermined space between one another in the Y direction.

Word lines WL1 to WL8 are bent in the Y direction in hook-up region B. Fringe patterns FR1 to FR8 for forming contacts are provided for each of word lines WL1 to WL8 in hook-up region B.

Other word lines WL not shown also extend into hook-up region B and are bent in the Y direction. Fringe patterns FR are provided to such word lines WL as well.

Fringe patterns FR1 to FR8 are arranged to be spaced from one another adjacent in the X-direction by a predetermined space (200 nm for example) or less. Fringe pattern FR1 is disposed so as to be the farthest in the X direction from the boundary of memory-cell array region Ar and hook-up region B. Fringe patterns FR2, FR3, . . . FR8 become closer to word-line group WLGA in the listed sequence. For each of fringe patterns FR1 to FR8, when a fringe pattern adjacent in the X direction does not exist or is spaced by a distance greater than a predetermined space, dummy patterns DP1 and DP2 are formed so that the space between the fringe patterns adjacent in the X direction is equal to or less than the predetermined distance. Dummy patterns DP3 are disposed between paired word-lines WLP extending the Y direction in hook-up region B. Each of paired word-lines WLP is formed of word lines WL adjacent in the X direction. Further, dummy patterns DP3 are formed within a predetermined distance from the ends (located in the Y-direction lower side in FIG. 35) of fringe patterns FR1 to FR8 of word lines WL1 to WL8. Dummy patterns DP 4 may be disposed between word line WL8 and other word lines WL in the memory-cell region.

Distance DPa between dummy pattern DP1 and fringe pattern FR1 is equal to or less than 200 nm as described earlier and is greater than distance DPb between fringe patterns FR. Further, distance DPc between the spreading portions of word lines WL of each paired word-lines WLP and fringe patterns FR is less than distance DPa in hook-up region B. The spreading portions are portions of word lines WL of each paired word-lines WLP extending in opposite directions in the X direction. Further, distance DPe between dummy patterns DP4 adjacent in the Y direction is less than distance DPa. Further, distances DPf between dummy patterns DP3 and paired word-lines WL are less than distance DPa.

Next, a description will be given on a manufacturing process flow of the above described structures with reference to FIGS. 30 to 35.

As illustrated in FIG. 30, first mandrel patterns 31 for the first sidewall transfer are formed above the insulating film. Gate insulating film 12 and gate electrode film 13 are formed for example above semiconductor substrate 11. Insulating film 14 serving as a processing film for the second sidewall transfer and an insulating film for forming the second mandrel patterns are formed above gate electrode film 13. An insulating film serving as a processing film for the first sidewall transfer is formed above the upper surface of the insulating film for forming the second mandrel pattern. An insulating film for forming first mandrel patterns is formed above the insulating film serving as a processing film for the first sidewall transfer. The insulating film for forming the first mandrel patterns is patterned by lithography to obtain first mandrel patterns 31.

First mandrel patterns 31 are configured by sub-portions, namely, first mandrel patterns 31a, 31b, and 31c. First mandrel patterns 31a correspond to word lines WL extending in the X direction. First mandrel patterns 31b located in hook-up region B correspond to the portions being bent in the Y direction. First mandrel patterns 31c located in hook-up region B are expanded in the X direction to form fringe patterns. The widths of first mandrel patterns 31a of first mandrel patterns 31 corresponding to word lines WL are approximately four times of first width D1. The spaces between the adjacent first mandrel patterns 31a are also approximately four times of first space L1. In the fifth embodiment, it is possible to form first mandrel patterns 31 without disposing dummy patterns. The formed first mandrel patterns 31 have substantially upright side surfaces.

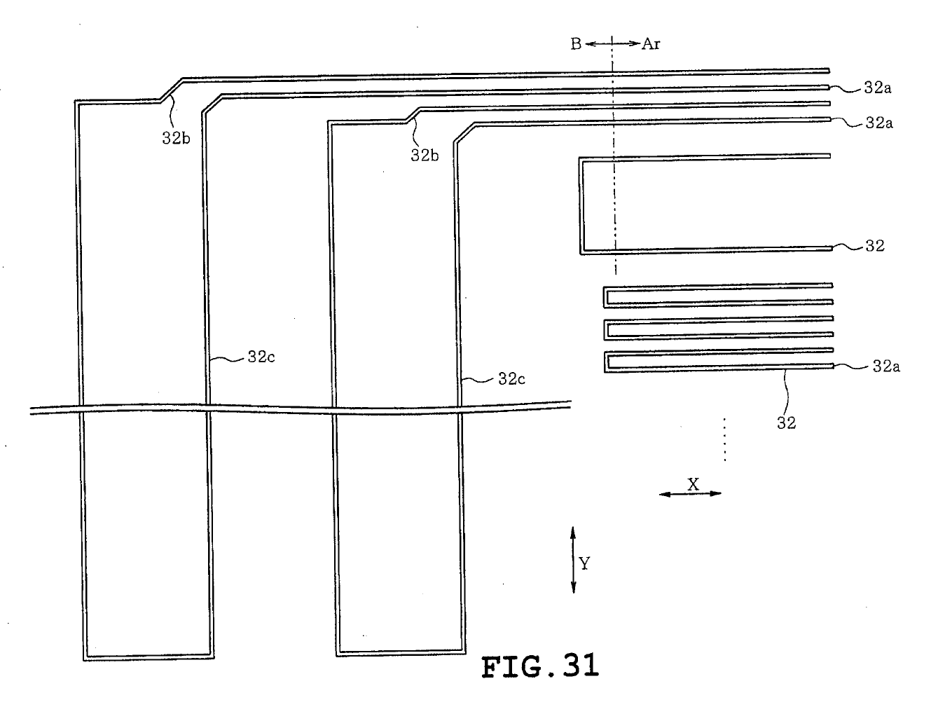

Next, as illustrated in FIG. 31, first sidewall patterns 32 are formed using first mandrel patterns 31.

First, mandrel patterns 31 are subjected to a slimming process to reduce the line width to approximately half of the original width. Then, a conformal film is formed along first mandrel patterns 31 subjected to the slimming process. The conformal film is etched back into shapes like spacers to obtain first sidewall patterns 32. First sidewall patterns 32 are formed so as to surround first mandrel patterns 31a to 31c. As a result, first sidewall patterns 32a to 32c each shaped like a loop are formed. Further, the width of first sidewall patterns 32 is approximately two times of first width D1 and the space between the first sidewall patterns 32 is approximately two times of first space L1.

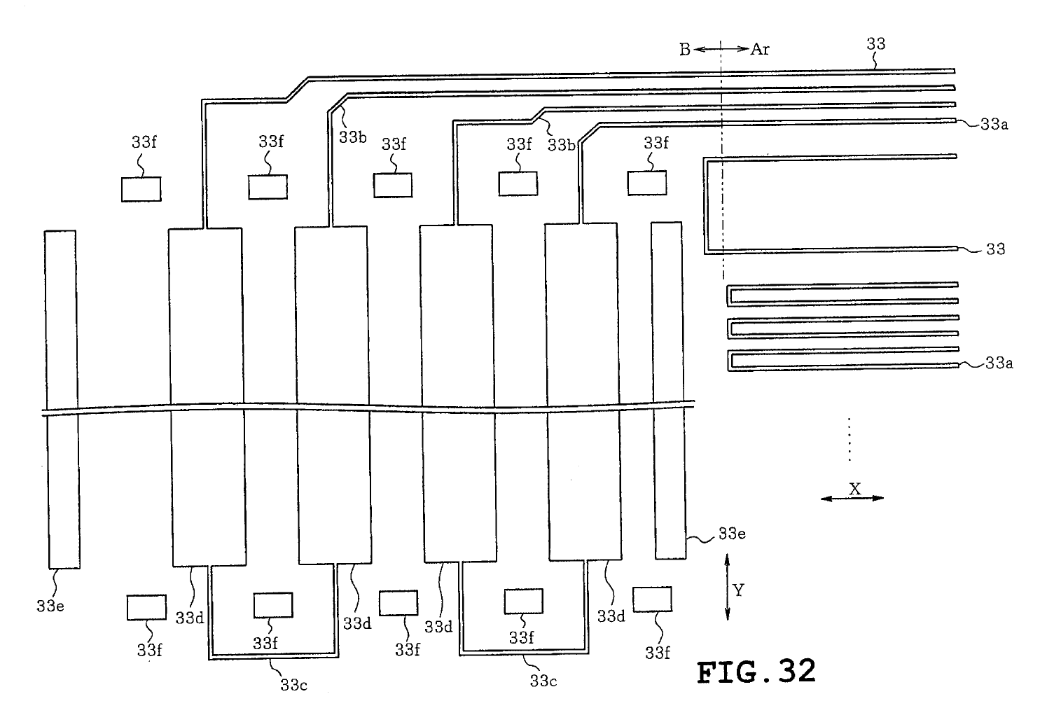

Next, as illustrated in FIG. 32, second mandrel patterns 33 for the second sidewall transfer are formed using first sidewall patterns 32a to 32c.

Resist masks for forming fringe patterns are formed and patterned in first sidewall patterns 32c in which wide spaces are provided for formation of fringe patterns.

Then, second mandrel patterns 33 for the second sidewall transfer is formed by etching the processing insulating film in the lower layer by RIE, using first sidewall patterns 32 (32a to 32c), resist masks, and dummy resist masks. First sidewall patterns 32, resist masks, and dummy resist masks are thereafter removed.

As a result, second mandrel patterns 33 are formed. Second mandrel patterns 33 have sub-portions, namely, second mandrel patterns 33a to 33c in locations corresponding to sidewall patterns 32a to 32c. Further, mandrel patterns 33d are formed using the resist masks provided above first sidewall patterns 32c shaped like loops. Further, dummy mandrel patterns 33e and 33f are formed using the dummy resist masks formed so as to surround second mandrel patterns 33d.

It is possible to form second mandrel patterns 33a to 33f having substantially upright side surfaces because dummy mandrel patterns 33e and 33f are disposed.

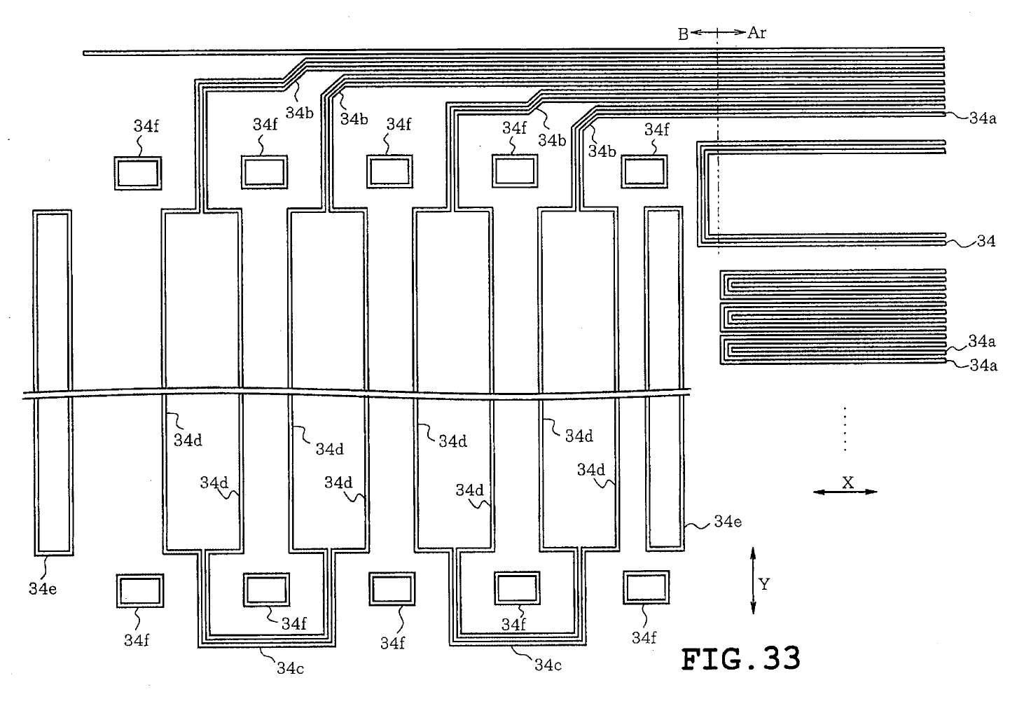

Then, as illustrated in FIG. 33, second sidewall patterns 34 are formed using second mandrel patterns 33 (including dummy mandrel patterns) which were formed in the above described manner.

Second mandrel patterns 33 are subjected to a slimming process to reduce the line width to approximately half of the original width. Then, a conformal film having thickness D1 is formed along second mandrel patterns 33 subjected to the slimming process. The conformal film is etched back into shapes like spacers to obtain second sidewall patterns 34.

Second sidewall patterns 34a to 34c are formed along both sides of second mandrel patterns 33a to 33c. Second sidewall patterns 34b may be referred to as paired wiring masks PAM. Further, second sidewall patterns 34d are formed in the shape of loops around second mandrel patterns 33d. Further, second sidewall patterns 34e and 34f are formed in the shape of loops around dummy mandrel patterns 33e and 33f. As described earlier, the side surfaces of second mandrel patterns 33a to 33c are formed to have steep side surfaces (large taper angles), in other words, substantially upright side surfaces. Thus, it is possible to form second sidewall patterns 34 disposed along the side surfaces to be substantially upright (large taper angles) with respect to the surface of the substrate.

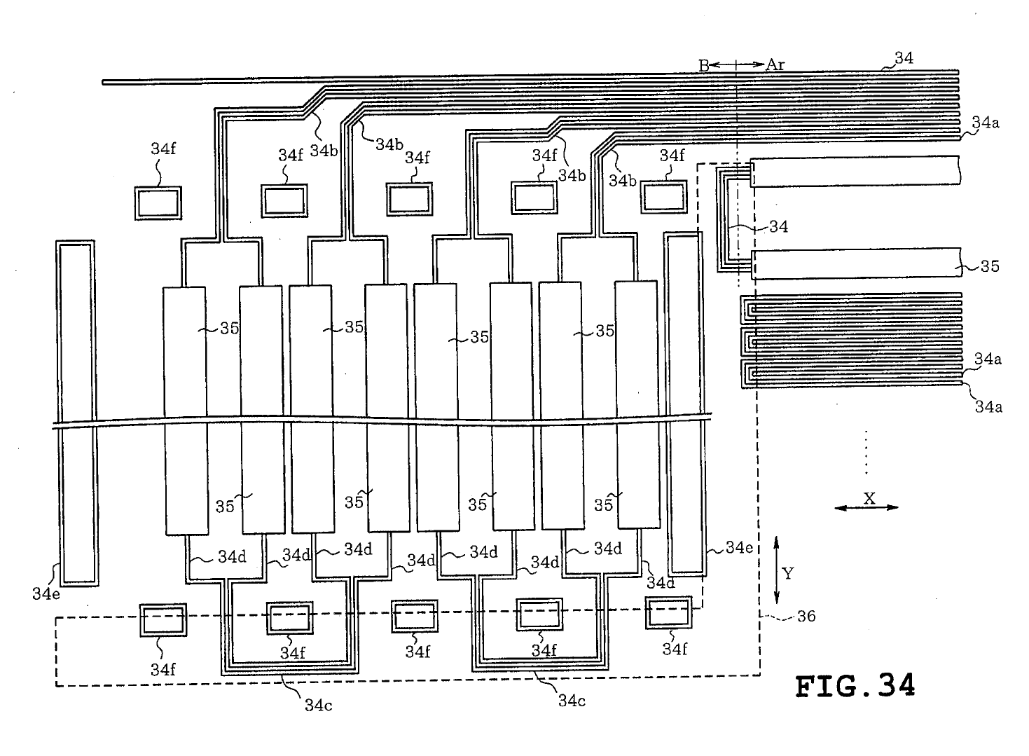

Then, as illustrated in FIG. 34, insulating film 14 and gate electrode film 13 in the lower layer are processed using second sidewall patterns 34 as masks. Resist patterns 35 for forming fringe patterns are formed above second sidewall patterns 34d and above second sidewall patterns 34 located between the portions where word lines WL are to be formed. In this state, the insulating film and the gate electrode film are etched by RIE using second sidewall patterns 34 and resist patterns 35 as masks. Second sidewall patterns 34, resist patterns 35, and the insulating films are thereafter removed. As a result, patterns of gate electrode films similar to the patterns illustrated in FIG. 34 are formed.

Next, a resist pattern for forming an opening in the portion indicated by broken line 36 in FIG. 34 is formed and the gate electrode films are removed by etching. As a result, word lines WL including word lines WL1 to WL8, fringe patterns FR including fringe patterns FR1 to FR8, and dummy patterns DP1 to DP4 are formed as illustrated in FIG. 35. Each fringe pattern FR is electrically independent of other fringe patterns FR. Further, it is possible to form word lines WL reliably without being dissipated during the etching of the gate electrode films.

In the fifth embodiment, it is possible to dispose dummy mandrel patterns in portions where the adjacent patterns are spaced from one another by a distance greater than a predetermined distance even when the sidewall transfer is carried out twice. More specifically, dummy mandrel patterns 33e and 33f are disposed in portions where the adjacent patterns are spaced from one another by a distance greater than a predetermined distance (200 nm for example) when forming second sidewall patterns 34 serving as processing masks. As a result, it is possible to form substantially upright second sidewall patterns 34 (34a to 34d). Second sidewall patterns 34 (34a to 34d) are processed so as to serve as etching masks used in RIE. Thus, it is possible to reliably process insulating films and gate electrode films without causing disconnections.

Further, ring-shaped dummy patterns DP3 may be disposed in the regions between the bent portions of paired word-lines WLP. Because the bent portions of the paired word-lines WLP tend to be distanced from one another, it is possible to prevent disconnections of word lines by disposing the dummy patterns.

### Sixth Embodiment

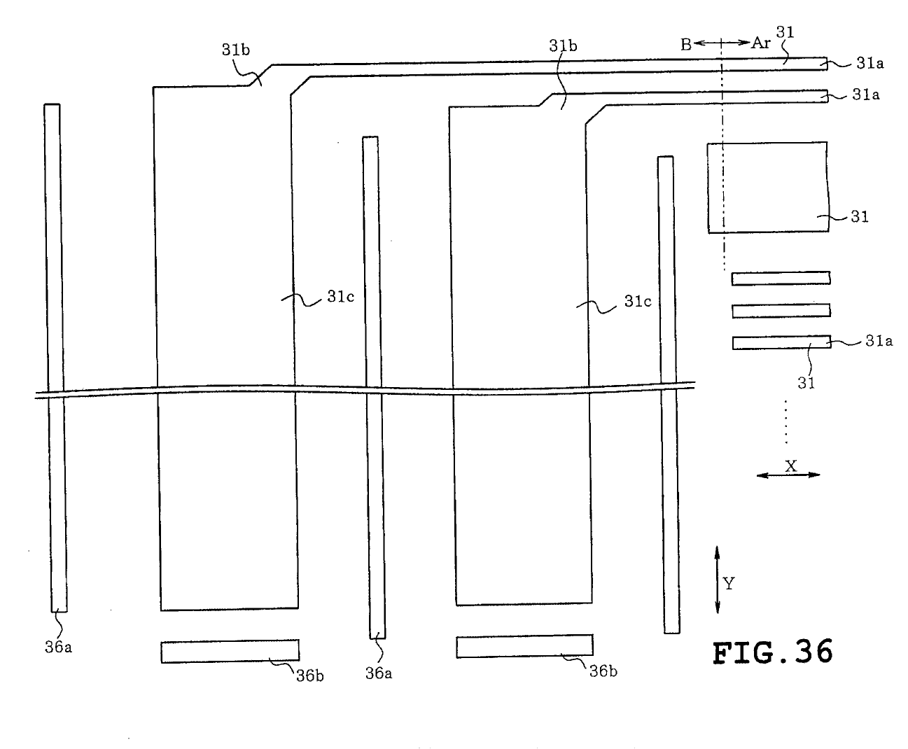

FIGS. 36 to 41 illustrate a sixth embodiment. Description will be given hereinunder based primarily on the differences from the fifth embodiment. In the sixth embodiment, dummy patterns are disposed in both the first and the second sidewall transfer processes.

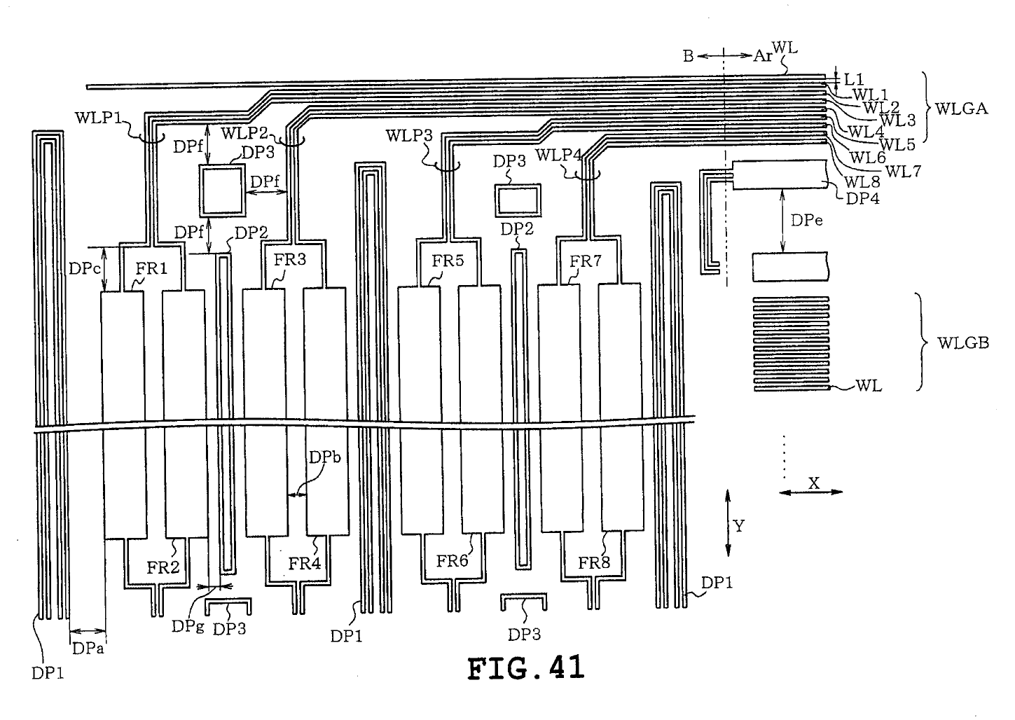

FIG. 41 is one example of a plan view of hook-up region B of word lines WL and fringe patterns FR formed by using sidewall transfer technique twice. In FIG. 41, for example, word lines WL1 to WL8 obtained by processing gate electrode film extend in the X direction as was the case in the fifth embodiment. Word lines WL1 to WL8 are disposed with a predetermined space between one another in the Y direction.

Word lines WL1 to WL8 are bent in the Y direction in hook-up region B. Fringe patterns FR1 to FR8 for forming contacts are provided for each of word lines WL1 to WL8 in hook-up region B. Other word lines WL not shown also extend into hook-up region B and are bent in the Y direction. Fringe patterns FR are provided to such word lines WL as well.

Fringe patterns FR1 to FR8 are arranged to be spaced from one another adjacent in the X-direction by a predetermined space (200 nm for example) or less.

For fringe patterns FR1 and FR8, when a fringe pattern adjacent in the X direction does not exist or is remote, dummy patterns DP1 are formed so that the space between fringe pattern FR1 and the adjacent pattern and the space between fringe pattern FR8 and the adjacent pattern are equal to or less than the predetermined distance, respectively. Dummy pattern DP1 is also formed between fringe patterns FR4 and FR5. Each dummy patterns DP1 is formed of a double loop. Dummy patterns DP2 are formed between fringe patterns FR2 and FR3 and between fringe patterns FR6 and FR7. Further, dummy patterns DP3 are formed near both Y-direction ends of dummy patterns DP2. The X-direction width of each dummy pattern DP3 is greater than the X-direction width of each dummy pattern DP2. Further, dummy pattern DP4 is provided between word line group WLGA and word line group WLGB. Wirings project downward from the Y-direction lower sides of fringe patterns FR1 to FR8. The projecting wirings are parts of word lines WL or dummy patterns.

Distance DPa between dummy pattern DP1 and fringe pattern FR1 is equal to or less than 200 nm as described earlier and is greater than distance DPb between fringe patterns FR. Further, distance DPc between the spreading portions of word lines WL of each paired word-lines WLP and fringe patterns FR is less than distance DPa in hook-up region B. The spreading portions are portions of word lines WL of each paired word-lines WLP extending in opposite directions in the X direction. Further, distance DPe between dummy patterns DP4 adjacent in the Y direction is less than distance DPa. Further, distance DPf between dummy patterns DP3 and paired word-lines WLP and between dummy patterns DP2 and dummy patterns DP3 are less than distance DPa.

Next, a description will be given on a manufacturing process flow of the above described structures with reference to FIGS. 36 to 41.

As illustrated in FIG. 36, first mandrel patterns 31 for the first sidewall transfer are formed above the insulating film. Gate insulating film 12 and gate electrode film 13 are formed for example above semiconductor substrate 11. Insulating film 14 serving as a processing film for the second sidewall transfer and an insulating film for forming the second mandrel patterns are formed above gate electrode film 13. An insulating film serving as a processing film for the first sidewall transfer is formed above the upper surface of the insulating film for forming the second mandrel pattern and is patterned as described in the fifth embodiment to obtain first mandrel patterns 31.

First mandrel patterns 31 are configured by first mandrel patterns 31a, 31b, and 31c. First mandrel patterns 31a correspond to word lines WL extending in the X direction. First mandrel patterns 31b located in hook-up region B correspond to the portions being bent in the Y direction. First mandrel patterns 31c located in hook-up region B are expanded in the X direction to form fringe patterns. First mandrel patterns 31c of first mandrel patterns 31 have large spaces between the adjacent patterns and thus, would result in gradual side surfaces (having small taper angles) when processed as they are.

Therefore, first dummy mandrel patterns 36a and 36b are disposed within a predetermined distance (200 nm for example) from the ends of the wide first mandrel patterns 31c for forming the fringe patterns so as to face first mandrel patterns 31c from three sides. As a result, the side surfaces of first mandrel patterns 31 and first dummy mandrel patterns 36a and 36b are formed to have steep inclination angles being substantially upright.

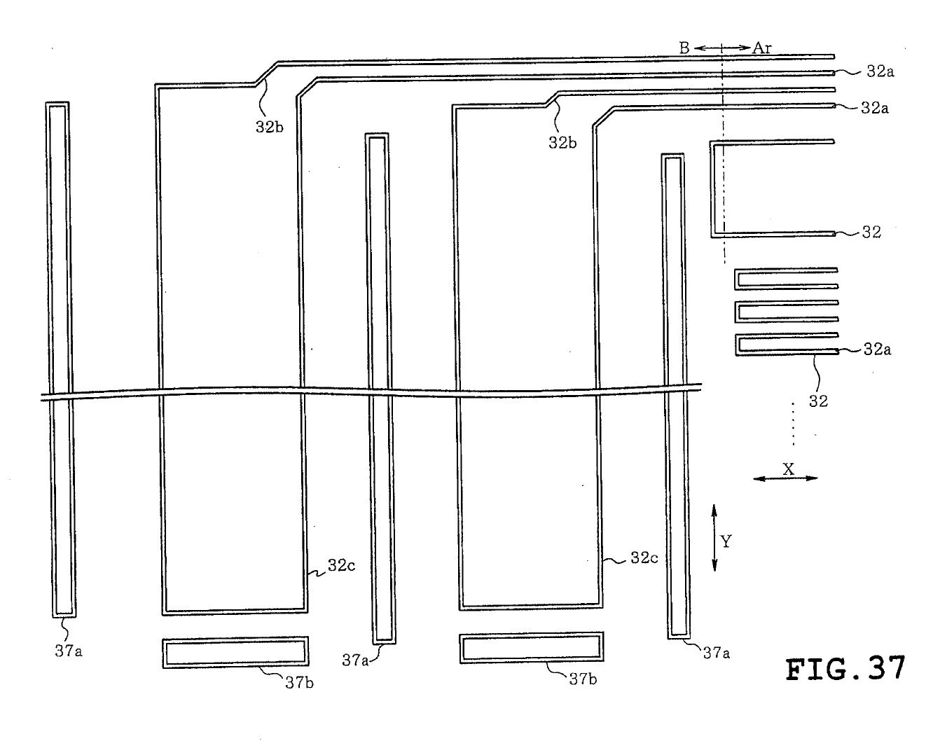

Next, as illustrated in FIG. 37, first mandrel patterns 31 and first dummy mandrel patterns 36a and 36b are subjected to a slimming process whereafter, first sidewall patterns 32 and first dummy sidewall patterns 37 are formed. First sidewall patterns 32a to 32c are formed in locations corresponding to first mandrel patterns 31a to 31c. First sidewall patterns 32a to 32c are formed in the shape of a loop so as to surround first mandrel patterns 31a to 31c. First dummy sidewall patterns 37 are configured by sub-portions, namely, first dummy sidewall patterns 37a and 37b formed in the shape of a loop so as to surround first dummy mandrel patterns 36a and 36b.

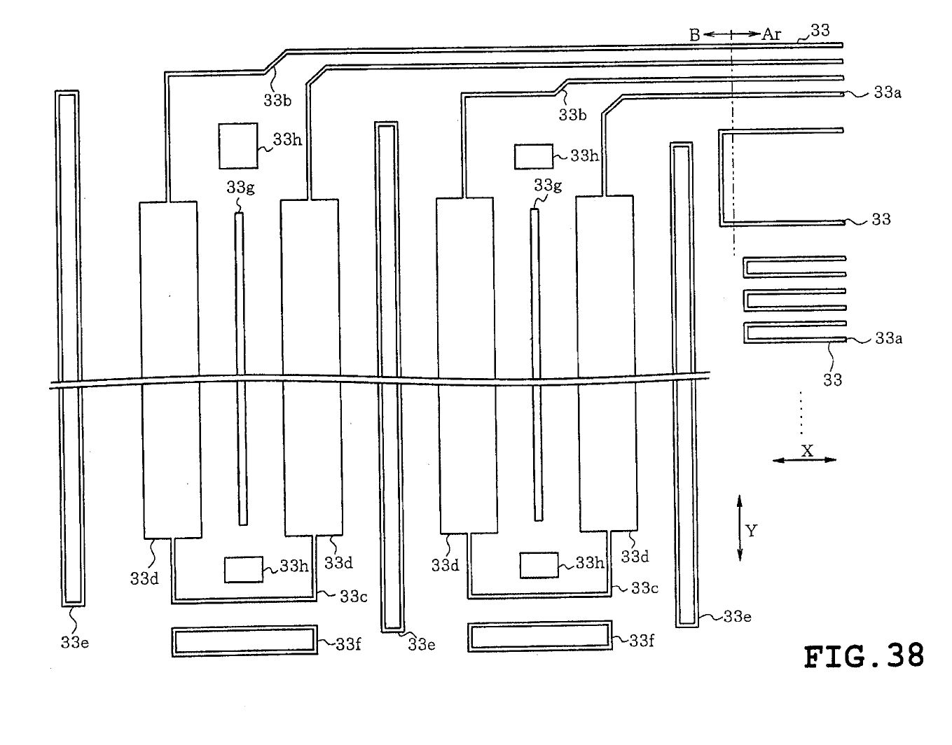

Then, as illustrated in FIG. 38, second mandrel patterns 33 for second sidewall transfer are formed using first sidewall patterns 32a to 32c and first dummy sidewall patterns 37a and 37b. More specifically, resist masks for forming fringe patterns are formed in first sidewall patterns 32c for forming fringe patterns. At the same time, dummy resist masks are formed in portions where the resist masks for forming fringe patterns are spaced by a distance greater than a predetermined distance from the adjacent structure.

Then, second mandrel patterns 33 for the second sidewall transfer is formed by etching the processing insulating film in the lower layer by RIE, using first sidewall patterns 32a to 32c, the resist masks, and the dummy resist masks. First sidewall patterns 32a to 32c, the resist masks, and the dummy resist masks are thereafter removed.

As a result, second mandrel patterns 33a to 33c are formed in the portions corresponding to first sidewall patterns 32a to 32c. Second mandrel patterns 33d are formed in the portions corresponding to the resist masks. Dummy mandrel patterns 33e and 33f are formed in the portions corresponding to first dummy sidewall patterns 37a and 37b. Dummy mandrel patterns 33g and 33h are formed in the portions corresponding to dummy resist masks. Dummy mandrel patterns 33g are disposed between second mandrel patterns 33d where dummy mandrel patterns 33e are not formed. Dummy mandrel patterns 33h are disposed in regions distanced in the Y direction by a predetermined space from both Y-direction ends of dummy mandrel patterns 33g.

It is possible to form second mandrel patterns 33 having steep (large taper angles) side surfaces being substantially upright because dummy mandrel patterns 33g and 33h are additionally disposed.

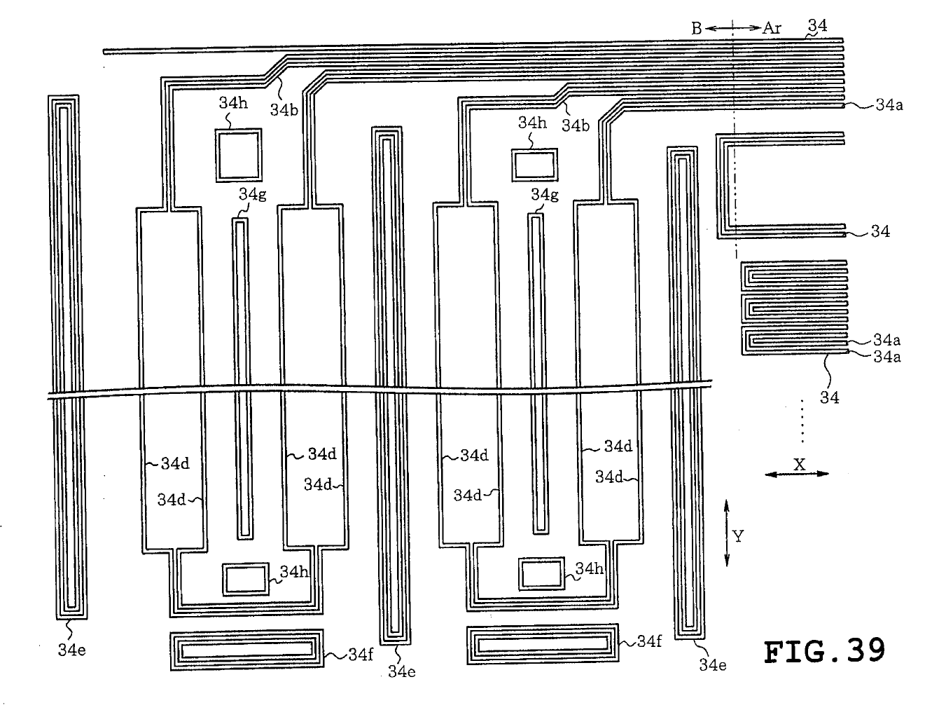

Then, as illustrated in FIG. 39, second sidewall patterns 34 are formed using second mandrel patterns 33 (including dummy mandrel patterns) which were formed in the above described manner. Then, a conformal film having thickness D1 is formed along second mandrel patterns 33. The conformal film is etched back by RIE into shapes like spacers to obtain second sidewall patterns 34.

Second sidewall patterns 34a to 34c are formed along both sides of second mandrel patterns 33a to 33c. Further, second sidewall patterns 34d are formed in the shape of loops around second mandrel patterns 33d. Further, second sidewall patterns 34e and 34f are formed in the shape of double loops around dummy mandrel patterns 33e and 33f. As described earlier, the side surfaces of second mandrel patterns 33 are formed to have steep side surfaces (large taper angles) being substantially upright. Thus, it is possible to form substantially upright second sidewall patterns 34 by using second mandrel patterns 33.

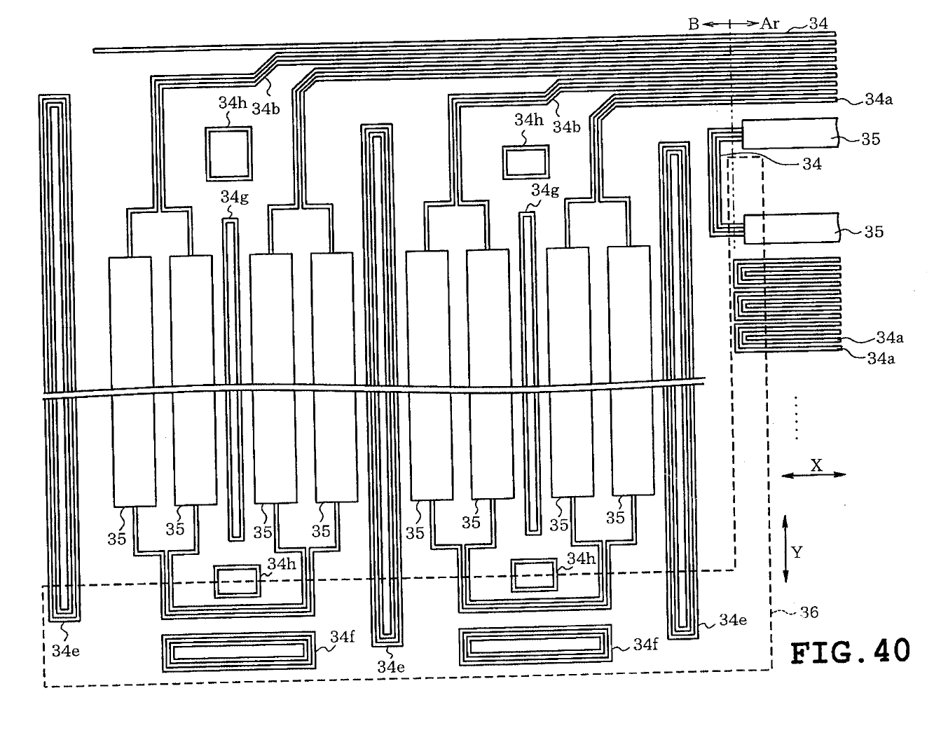

Then, as illustrated in FIG. 40, insulating film 14 and gate electrode film 13 in the lower layer are processed using second sidewall patterns 34 as masks. Resist patterns 35 for forming fringe patterns are formed above second sidewall patterns 34d and above second sidewall patterns 34 located between the portions where word lines WL are to be formed. In this state, insulating film 14 and gate electrode film 13 are etched by RIE using second sidewall patterns 34 and resist patterns 35 as masks. Second sidewall patterns 34, resist patterns 35, and the insulating films are thereafter removed. As a result, patterns of gate electrode films 13 similar to the patterns illustrated in FIG. 40 are formed.

Next, a resist pattern for forming an opening in the portion indicated by broken line 36 in FIG. 40 is formed and the gate electrode films are removed by etching. As a result, word lines WL including word lines WL1 to WL8, fringe patterns FR including fringe patterns FR1 to FR8, and dummy patterns DP1 to DP4 are formed as illustrated in FIG. 41. Each fringe pattern FR is electrically independent of other fringe patterns FR. Further, it is possible to form word lines WL reliably without being dissipated during the etching of the gate electrode films.

In the sixth embodiment, it is possible to dispose first dummy mandrel patterns 36a and 36b in portions where the adjacent patterns are spaced from one another by a distance greater than a predetermined distance (200 nm for example) when forming first sidewall patterns 32 serving as processing masks. It is further possible to dispose dummy mandrel patterns 33g and 33h in portions where the adjacent patterns are spaced from one another by a distance greater than a predetermined distance (200 nm for example) when forming second sidewall patterns 34 serving as processing masks. As a result, it is possible to dispose dummy patterns DP2 even when fringe patterns FR (fringe patterns FR2 and FR3) connected to word lines of adjacent paired word-lines WLP are spaced by a distance greater than a predetermined distance. Further, it is possible to dispose dummy patterns DP1 even when fringe patterns FR (fringe patterns FR4 and FR5) connected to word lines of adjacent paired word-lines WLP are spaced by a distance greater than a predetermined distance.

As a result, it is possible to form first sidewall patterns 32a to 32c and second sidewall patterns 34a to 34d to be substantially upright. Second sidewall patterns 34a to 34d are processed so as to serve as etching masks used in RIE. Thus, it is possible to reliably process insulating films and gate electrode films without causing disconnections.

### Seventh Embodiment

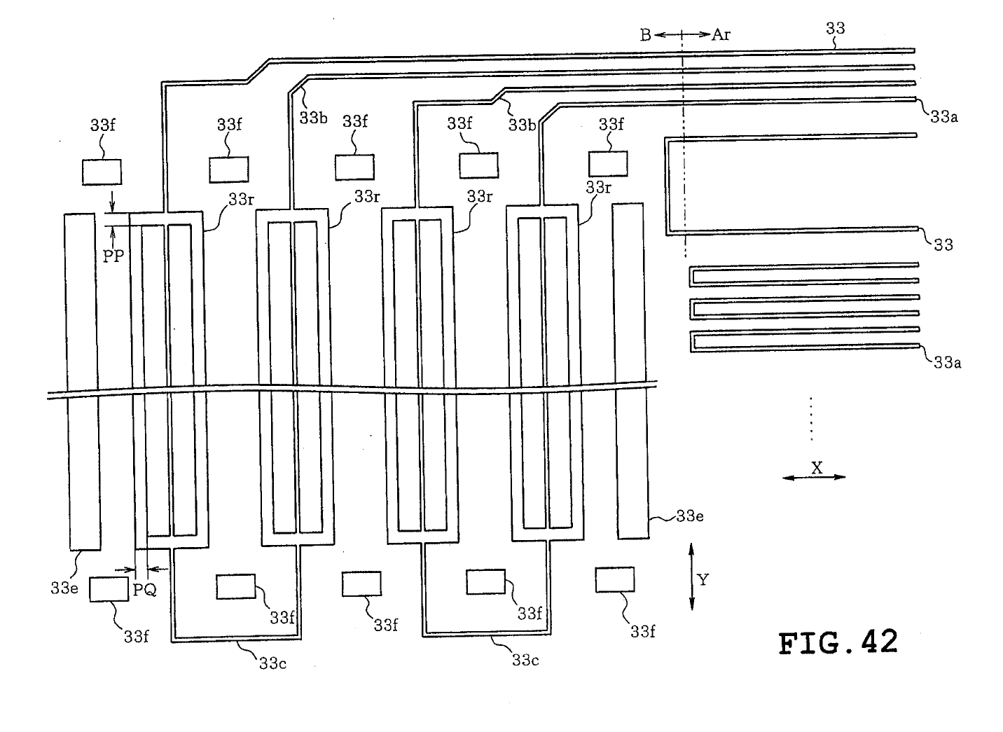

FIGS. 42 to 45 illustrate a seventh embodiment. Description will be given hereinunder based primarily on the differences from the fifth embodiment. The seventh embodiment differs from the fifth embodiment in that second mandrel patterns 33d formed in the portions corresponding to first sidewall patterns 32a to 32c are each shaped like a loop.

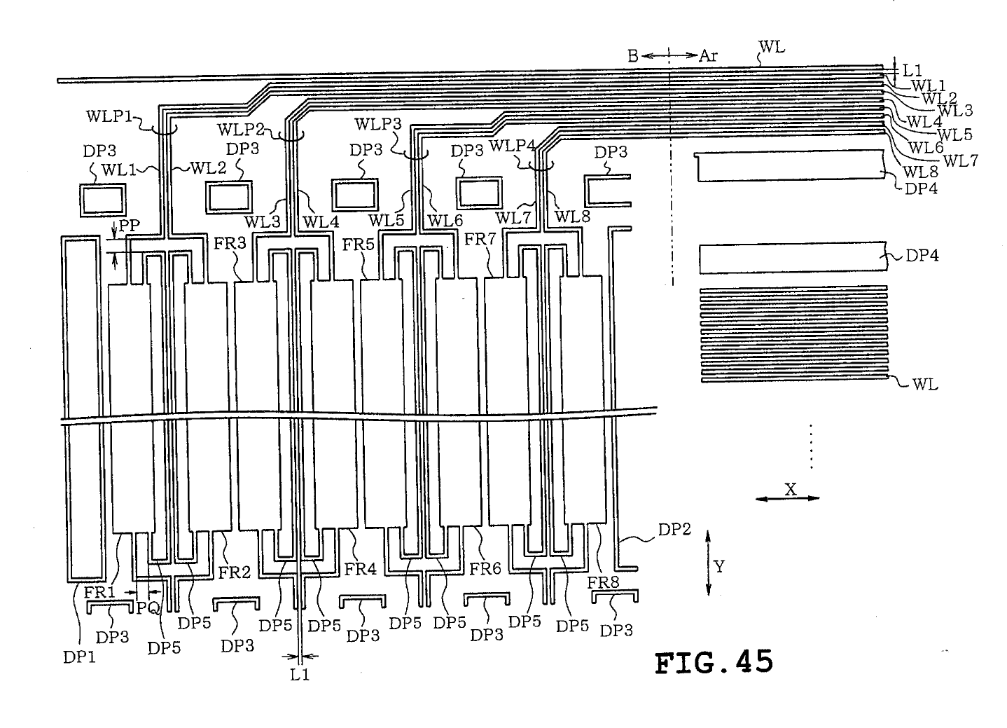

FIG. 45 is one example of a plan view of hook-up region B of word lines WL and fringe patterns FR formed by using sidewall transfer technique twice. In FIG. 45, for example, word lines WL1 to WL8 obtained by processing gate electrode film 13 extend in the X direction as was the case in the fifth embodiment. Word lines WL1 to WL8 are disposed with a predetermined space between one another in the Y direction.

Word lines WL1 to WL8 are bent in the Y direction in hook-up region B and are distanced from one another by a predetermined space. Fringe patterns FR1 to FR8 for forming contacts are provided for each of word lines WL1 to WL8 in hook-up region B. Other word lines WL not shown also extend into hook-up region B and are bent in the Y direction. Fringe patterns FR are provided to such word lines WL as well.

Fringe patterns FR1 to FR8 are arranged in the manner substantially identical to the arrangement of the fifth embodiment. That is, fringe patterns FR1 to FR8 are arranged to be spaced from one another adjacent in the X-direction by a predetermined space (200 nm for example) or less.

For fringe patterns FR1 and FR8, when a fringe pattern adjacent in the X direction does not exist or is spaced apart by a distance greater than a predetermined distance, dummy patterns DP1 and DP2 are formed.

Dummy patterns DP3 are disposed between paired word-lines WLP extending in the Y direction in hook-up region B. Each of paired word-lines WLP is formed of word lines WL adjacent in the X direction. Further, dummy patterns DP3 are formed so as to be spaced by a predetermined distance in the Y direction from the ends (located in the Y-direction lower side in FIG. 45) of fringe patterns FR1 to FR8. Dummy patterns DP 4 may be disposed between word line WL8 and other word lines WL in the memory-cell region.

Further, in the seventh embodiment, dummy pattern portions DP5 are formed in the regions where fringe patterns FR1 to FR8 are formed in the configuration illustrated in FIG. 45. More specifically, pairs of dummy pattern portions DP5 are disposed inside the spreading portions of the pairs of word lines WL1 to WL8 belonging to paired word-lines WLP1 to WLP4 located in hook-up region B. The spreading portions are portions of word lines WL1 to WL8 of each paired word-lines WLP1 to WLP4 that extend in opposite directions in the X direction, and are located in the portions where paired word-lines WLP1 to WLP4 extend in the Y direction. Stated differently, dummy patterns DP5 are each formed in the shape of a loop in the substantially rectangular space located in the region where word lines WL1 to WL8 spread out.

In each pair of dummy patterns DP5, the two dummy patterns DP5 are spaced from one another by distance L1. In each of paired word-lines WLP1 to WLP4, the portions of dummy patterns DP5 extending in the X direction are spaced from word lines WL extending in the X direction by distance PP as indicated in FIG. 45. Distance PP is equal to or greater than the critical dimension achievable by photolithography. In the seventh embodiment, distance PP is specified to be close to the critical dimension. Further, the portions of dummy patterns DP5 extending the Y direction are spaced from word lines WL extending in the Y direction by distance PQ. Distance PP and distance PQ are substantially equal.

Fringe patterns FR overlap with the outer peripheral sides of loop-shaped dummy patterns DP5 located adjacent to word lines WL. Fringe patterns FR connected to word lines WL of paired word-lines WLP are electrically isolated because the two dummy patterns DP5 forming the pair are spaced from one another by distance L1.

Next, a description will be given on the manufacturing process flow of the above described structure with reference to FIGS. 42 to 45.

First, the structure illustrated in FIG. 30 of the fifth embodiment is formed. Gate insulating film 12 and gate electrode film 13 are formed for example above semiconductor substrate 11. Insulating film 14 serving as a processing film for the second sidewall transfer and an insulating film for forming the second mandrel patterns are formed above gate electrode film 13. An insulating film used in the first sidewall transfer is formed above the upper surface of the insulating film for forming the second mandrel patterns. Then, an insulating film for the first mandrel patterns are formed and thereafter patterned by photolithography to obtain first mandrel patterns 31. Next, first sidewall patterns 32 illustrated in FIG. 31 are formed.

Then, as illustrated in FIG. 42, second mandrel patterns 33 for use in the second sidewall transfer is formed using first sidewall patterns 32. Resist masks shaped like rectangular rings are formed for forming fringe patterns in first sidewall patterns 32c where the fringe patterns are to be formed. The resist masks shaped like rectangular rings have width PP which is close to critical dimension achievable by photolithography. At the same time, dummy resist masks may be formed in portions where the resist masks for forming the fringe patterns are spaced by a distance greater than a predetermined distance from the adjacent structure.

Then, second mandrel patterns 33 for the second sidewall transfer is formed by etching the insulating film in the lower layer by RIE, using first sidewall patterns 32a to 32c, the resist masks, and the dummy resist masks. First sidewall patterns 32a to 32c, the resist masks, and the dummy resist masks are thereafter removed.

As a result, second mandrel patterns 33a to 33c are formed in the portions corresponding to first sidewall patterns 32a to 32c.

Thus, second mandrel patterns 33a to 33c are formed in the portions corresponding to first sidewall patterns 32a to 32c. Further, second mandrel patterns 33r shaped like rectangular rings are formed above first sidewall patterns 32c shaped like loops by using resist masks shaped like rectangular rings. Further, dummy mandrel patterns 33e and 33f are formed using dummy resist masks other than those used for forming mandrel patterns 33r shaped like rectangular rings.

It is possible to form second mandrel patterns 33a to 33f and 33r so as to have substantially upright side surfaces because dummy mandrel patterns 33e and 33f are disposed when forming second mandrel patterns 33.

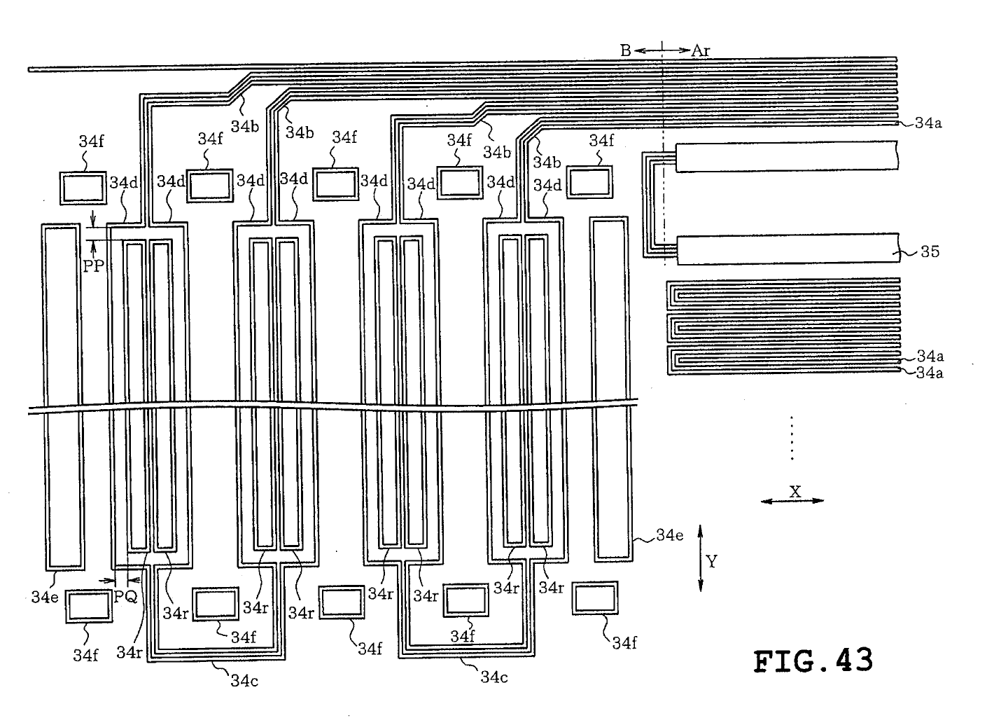

Then, as illustrated in FIG. 43, second sidewall patterns 34 are formed using second mandrel patterns 33 (including dummy mandrel patterns). A conformal film having thickness D1 is formed along the upper surfaces of second mandrel patterns 33. The conformal film is etched back by RIE into shapes like spacers to obtain second sidewall patterns 34. Second sidewall patterns 34b may be referred to as paired wiring masks PAM. Further, second sidewall patterns 34d are formed in the outer peripheral sides of second mandrel patterns 33r shaped like rectangular rings. In the inner peripheral side of each dummy mandrel pattern 33r, a couple of dummy sidewall pattern 34r is disposed so as to form a pair. Dummy sidewall patterns 34r of the pair are spaced from one another in the X direction by space L1. Each of the pair of dummy sidewall patterns 34r is spaced by distance PP in the Y direction and distance PQ in the X direction from second sidewall patterns 34d located in the outer peripheral side. Stated differently, a couple of dummy sidewall patterns 34r shaped like a rectangular rings is disposed in the inner side of each portion 34d of second sidewall patterns 34 located in the outer peripheral side.

In the seventh embodiment, distance PP and distance PQ are substantially equal. Further, second sidewall patterns 34e and 34f shaped like loops are formed around dummy mandrel patterns 33e and 33f. As described earlier, second mandrel patterns 33a to 33c have steep side surfaces (large taper angles), in other words, substantially upright side surfaces. Thus, it is possible to form substantially upright (large taper angles) second sidewall patterns 34.

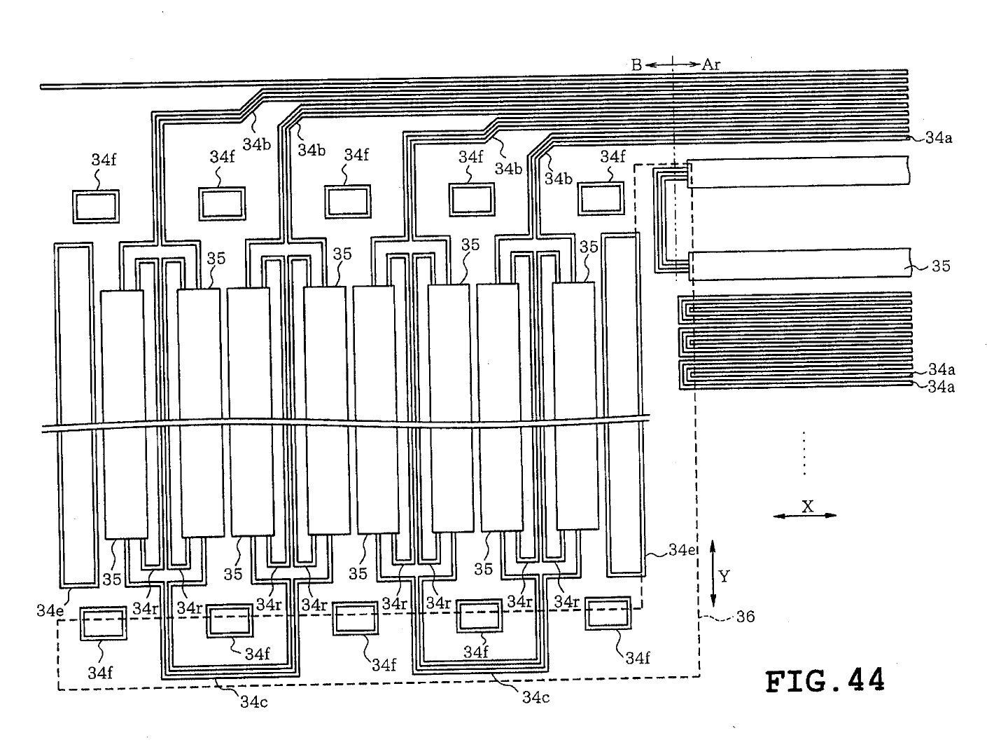

Then, as illustrated in FIG. 44, insulating film 14 and gate electrode film 13 in the lower layer are processed using second sidewall patterns 34 as masks. Resist patterns 35 for forming fringe patterns are formed above portions of second sidewall patterns 34d extending in the Y direction of second sidewall patterns 34. Resist patterns 35 for forming fringe patterns are also formed so as to partially cover the upper surfaces extending in the Y direction of dummy sidewall patterns 34r located adjacent to second sidewall patterns 34d. Resist patterns 35 are not formed in regions located between the adjacent dummy sidewall patterns 34r. Resist patterns 35 are formed above second sidewall patterns 34 located between the portions where word lines WL are to be formed. In this state, insulating film and gate electrode film are etched by RIE using second sidewall patterns 34 and resist patterns 35 as masks. Second sidewall patterns 34, resist patterns 35, and the insulating films are thereafter removed. As a result, patterns of gate electrode films similar to the patterns illustrated in FIG. 44 are formed.

In the seventh embodiment, it is possible to obtain the effects similar to those obtained in the fifth embodiment.

Further, in the seventh embodiment, second mandrel patterns 33r shaped like rectangular rings are provided instead of second mandrel patterns 33d. As a result, a couple of dummy sidewall patterns 34r is formed in hook-up region B in locations where each of word lines WL of paired word-lines WLP spreading in the X direction is extended in the Y direction. As a result, it is possible to prevent filling of the spaces between word lines WL in the regions where word lines WL spread out when the manufacturing process flow includes, for example, a step of forming an insulating film (a silicon oxide film made of for example plasma silane) providing poor gap fill capability.

Further, it is possible to form second mandrel patterns 33r shaped like rectangular rings to have width PP equal to or greater than the critical dimension achievable by photolithography. As a result, no special process steps need to be added in order to obtain the effects described above.

In the seventh embodiment, second mandrel patterns 33r shaped like rectangular rings are configured to have width PP throughout the entire perimeter. Critical dimension achievable by photolithography may be applied to width PP and width PQ may be configured to be greater than width PP.

### Eighth Embodiment

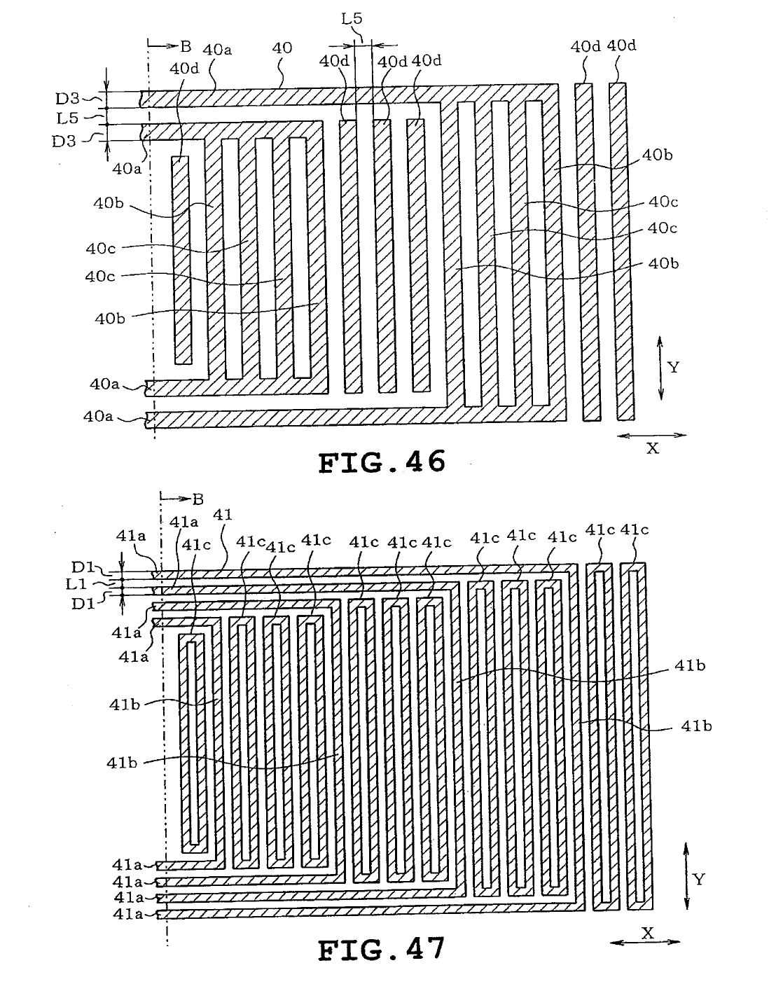

FIGS. 46 to 49 illustrate an eighth embodiment. Description will be given hereinunder based primarily on the differences from the third embodiment. In the eighth embodiment, sublithographic line-and-space patterning is performed using a sidewall transfer technique when forming gate electrodes of memory-cell transistors in NAND flash memory device 100. NAND flash memory device 100 is provided with air gaps between the gate electrodes. The gate electrodes are interconnected by word lines and the end portion of each word line hooks up with other circuit elements in the hook-up region.

The space between the word lines are wider in the hook-up region than in the memory-cell region. In the case when an insulating film for forming air gaps are formed, abnormal oxidation or intrusion of resist into the air gaps, possibly causing inter-gate leakage current, may occur when the air gaps are not closed at the end portions of word lines.

FIG. 49 is one example of a figure illustrating a layout of fringe patterns formed in hook-up region B of word lines WL.

In hook-up region B, four word lines WL1 to WL4 extending in the X direction are formed in the upper side of cut region Cb and four word lines WL5 to WL8 extending in the X direction are formed in the lower side of cut region Cb. In the memory-cell region, word lines WL1 to WL8 each having width D1 are spaced from one another in the Y direction by space L1. In hook-up region B, word lines WL1 to WL4 are bent downward along the Y direction to form word line hook-up parts WL1a to WL4a (also generally represented as WLa in the specification). Further, in hook-up region B, word lines WL5 to WL8 are bent upward along the Y direction to form word line hook-up parts WL5a to WL8a.

The space between word lines WL in word line hook-up parts WL1a to WL8a is greater than the space between word lines WL in the memory cell region. Word line hook-up parts WL1a to WL8a are provided with fringe patterns FR1 to FR8, respectively. Fringe patterns FR1 to FR4 are disposed next to one another in the X direction. Fringe patterns FR5 to FR8 are also disposed next to one another in the X direction. Fringe patterns FR1 to FR4 are spaced from fringe patterns FR5 to FR8 in the Y direction by a predetermined distance so as to face fringe patterns FR5 to FR8.

Dummy patterns DP1, serving as dummy wiring patterns, are disposed in both X-direction sides of word line hook-up parts WL1a to WL8a. Dummy patterns DP2, serving as dummy wiring patterns, are disposed between dummy patterns DP1 adjacent in the X direction. Dummy patterns DP1 are connected to fringe patterns FR adjacent in the Y direction respectively. Dummy patterns DP2 are isolated from fringe patterns FR and dummy patterns DP1. Both dummy patterns DP1 and DP2 have width D1 and both dummy patterns DP1 and DP2 are spaced from one another in the X direction by space L1.

In the regions for forming fringe patterns FR, space between the adjacent word line hook-up parts WLa is greater than the space between the adjacent word lines WL. However, dummy patterns DP1 and DP2 are formed in the regions for forming fringe patterns FR. Thus, the structures formed in hook-up region B have the same pitch as the structures formed in the memory-cell region. As a result, it is possible to arrange the space between the patterns in word line hook-up parts WLa to be substantially the same as the space between word lines WL. Thus, it is possible to minimize the possibility of the air gaps being re-opened and thereby inhibiting the intrusion of resists, LPCVD films, or the like, into the re-opened air gaps.

Next, a description will be given on the manufacturing process flow of word lines WL and fringe patterns FR. Gate insulating film 12 and gate electrode film 13 are formed above semiconductor substrate 11 and gate processing insulating film 14 is formed above the upper surface of gate electrode film 13.

Above gate processing insulating film 14, an insulating film for forming mandrel patterns are formed as illustrated in FIG. 46, and the formed insulating film is patterned by lithography to obtain mandrel patterns 40.

Among mandrel patterns 40 (40a, 40b, 40c, and 40d) formed above gate processing insulating film 14, mandrel patterns 40a extending in the X direction and serving as word lines are formed as a line-and-space pattern having a pitch substantially double of the pitch of word lines WL of the final structure (width D3=2×D1, space L5=2×L1). Mandrel patterns 40b for forming word line hook-up parts WLa extend in the Y direction and have width D3. Mandrel patterns 40a are connected to both ends of the mandrel patterns 40b. The distance between mandrel patterns 40b adjacent in the X direction is greater than width D1. Further, mandrel patterns 40a and 40b in hook-up region B, when combined, may be described as being shaped like loops.

Two lines of dummy mandrel patterns 40c and three lines of dummy mandrel patterns 40d may be provided in the spaces located between the regions where word line hook-up parts WLa are to be disposed next to one another in the X direction. Each of dummy mandrel patterns 40c have width D3 and extend in the Y direction. Dummy mandrel patterns 40c are spaced from one another in the X direction by space L5. Each of dummy mandrel patterns 40c is connected to mandrel patterns 40a located above and below portion 40c. Further, each of dummy mandrel patterns 40d have width D3 and extend in the Y direction. Dummy mandrel patterns 40d are spaced from one another in the X direction by space L5. Dummy mandrel patterns 40d are separated from mandrel patterns 40a located above and below dummy mandrel patterns 40d. Mandrel patterns 40b serving as word line hook-up parts and dummy mandrel patterns 40c are connected by common mandrel patterns 40a located above and below mandrel patterns 40b and 40c. Mandrel patterns 40b to 40d are disposed in the X direction with space L5 therebetween.

Next, as illustrated in FIG. 4′7, sidewall patterns 41 are formed using mandrel patterns 40. Mandrel patterns 40 are subjected to a slimming process so that the width of mandrel patterns 40 is reduced to width D1 which is approximately half of the original width. After the slimming process, an insulating film for forming the sidewall patterns is formed above the entire surface. The insulating film is thereafter etched back by RIF so as to be shaped like spacers. As a result, sidewall patterns are formed along both sidewalls of mandrel patterns 40 subjected to the slimming process.

Sidewall patterns 41 are configured by sub-portions, namely, sidewall patterns 41a, 41b, and dummy sidewall patterns 41c, corresponding to mandrel patterns 40 subjected to the slimming process. Sidewall patterns 41a and 41b are connected and extend along mandrel patterns 40a and 40b subjected to the slimming process. Dummy sidewall patterns 41c are formed in the shape of loops around mandrel patterns 40b and dummy mandrel patterns 40c and 40d subjected to the slimming process. Sidewall patterns 41a and 41b and dummy sidewall patterns 41c have width D1 and are all spaced from one another by space L1.

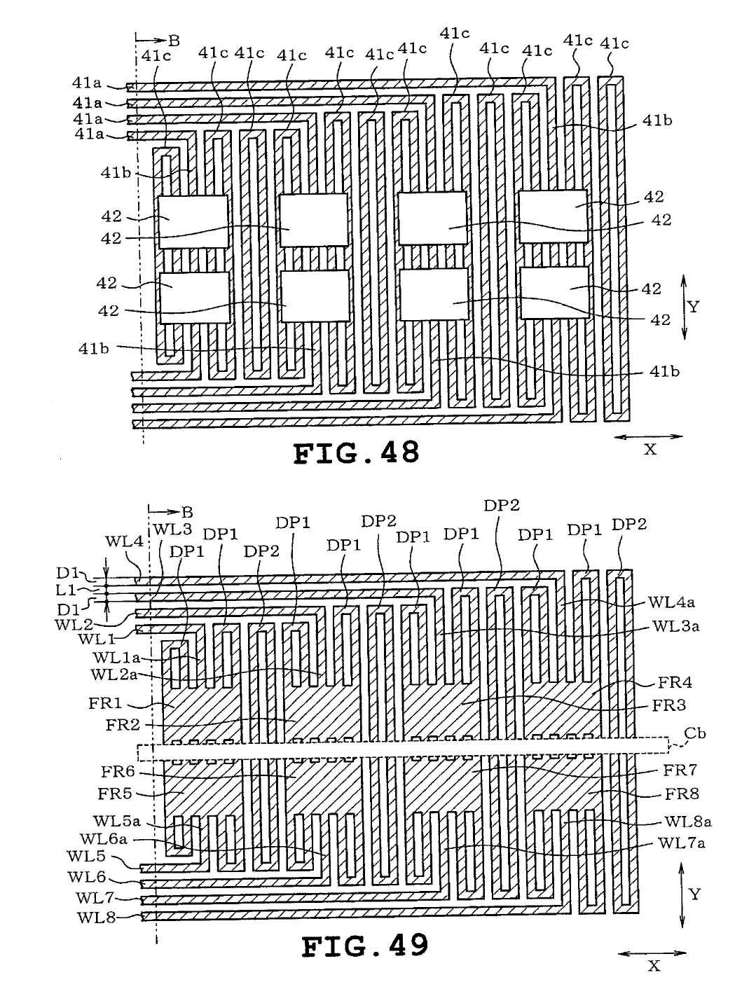

Next, as illustrated in FIG. 48, resist patterns 42 for forming the fringe patterns are formed in hook-up region B. Resist patterns 42 are located substantially in the central portions of sidewall patterns 41b so as to overlap with dummy sidewall patterns 41c disposed in the left and right sides of sidewall patterns 41b. Further, two resist patterns 42 are disposed above a single line of sidewall pattern 41b so as to be adjacent to one another in the Y direction with a predetermined space.

Next, as shown in FIG. 49, the processing insulating film and the gate electrode film in the lower layer are etched by RIE using sidewall patterns 41a and 41b, dummy sidewall patterns 41c, and resist pattern 42 as masks. As a result, word lines WL1 to WL8 are formed in the memory-cell region and word line hook-up parts WL1a to WL8a are formed in hook-up region B. Fringe patterns FR1 to FR8 are formed so as to correspond to the shape of resist patterns 42. Further, dummy patterns DP1 and DP2 are formed in locations corresponding to dummy sidewall patterns 41c. The gate electrodes and word lines described earlier are formed in this step.

Then, word line hook-up parts WLa and dummy patterns DP1 and DP2 located between fringe patterns FR1 to FR4 and fringe patterns FR5 to FR8 are removed by lithography and etching to form cut region Cb. Cut region Cb is formed so as to extend in the X direction between fringe patterns FR1 to FR4 and fringe patterns FR5 to FR8 disposed in the Y direction. As a result, the connected portions between fringe patterns FR1 to FR4 and fringe patterns FR5 to FR8 are disconnected and each of fringe patterns FR1 to FR8 become electrically independent.

Further, word line hook-up parts WL1a to WL8a are connected to the central portion of the corresponding fringe patterns FR1 to FR8. Dummy patterns DP1 are connected to fringe patterns FR1 to FR8 so as to be located in both sides of each of word line hook-up parts WL1a to WL8a. Further, each dummy pattern DP2 is disposed in an isolated state between fringe patterns FR.

The above described step forms patterns of gate electrodes and word lines in the memory-cell region. Then, an oxide film providing extremely poor side-step coverage is deposited by CVD above the entire surface in order to form air gaps. As a result, the oxide film does not fill the gaps between word lines WL having first space L1, but instead, extends over the gaps to form air gaps between the gate electrodes. The spaces between the wirings disposed between word lines WL1-WL8 to fringe patterns FR1-FR8 are substantially equal to width D1. More specifically, the spaces between the wirings including word line hook-up parts WL1a to WL8a and dummy patterns DP1 and DP2 located in hook-up region B are substantially equal to the spaces between word lines WL in the memory-cell region. Stated differently, there are no wide spaces between the word lines in hook-up region. The gaps between word line hook-up parts WL1a to WL8a to which word lines WL1 to WL8 are connected and dummy patterns DP1 are terminated by fringe patterns FR1 to FR8. Thus it is possible to reliably close the gaps between word lines WL1 to WL8 when forming the air gaps.

In the eight embodiment described above, it is possible to arrange the structures located between the portions where the word lines are bent to be distanced from one another by space L1 by disposing dummy patterns DP1 and DP2 in the regions where word line hook-up parts WL1a to WL8a of word lines WL1 to WL8 are formed. As a result, it is possible to minimize the formation of openings when the insulating film is being formed for forming the air gaps. Thus, it is possible to prevent intrusion of resists and intrusion of gases generated during the formation an interlayer insulating film through the formed openings.

### Modified Example of Eighth Embodiment

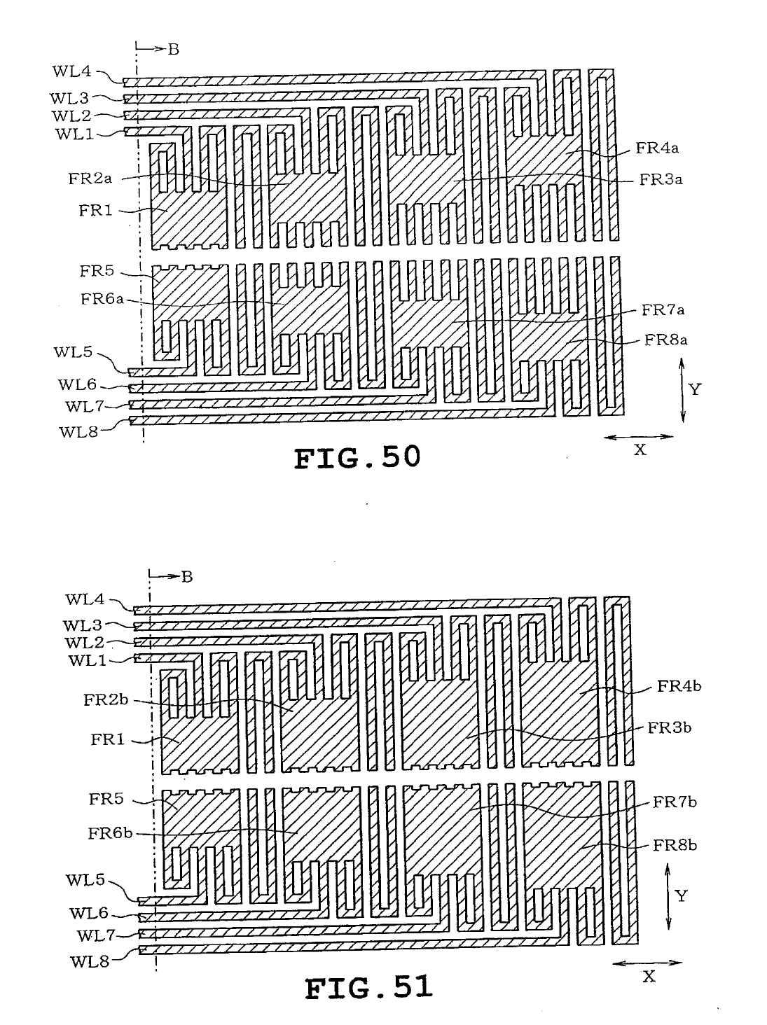

FIGS. 50 and 51 illustrate the modified example of the eighth embodiment.

The example illustrated in FIG. 50 differs from the eighth embodiment in that fringe patterns FR2 to FR4 and fringe patterns FR6 to FR8 are replaced by fringe patterns FR2a to FR4a and fringe patterns FR6a to FR8a. For example, as illustrated in FIG. 50, fringe patterns FR are arranged so as to increase the Y direction distances from cut region Cb as the X direction distances from the memory-cell region become greater. As a result, it is possible to approximate the distances between word lines WL2 to WL4 and their corresponding fringe patterns FR2a to FR4a to the distance between word line WL1 and fringe pattern FR1. Thus, it is possible to substantially uniform the shapes of the structures from each word line WL to the corresponding fringe pattern FR and thereby reduce process variations.

The example illustrated in FIG. 51 differs from the eighth embodiment in that fringe patterns FR2 to FR4 and fringe patterns FR6 to FR8 are replaced by fringe patterns FR2b to FR4b and fringe patterns FR6b to FR8b. In addition to the modified structure illustrated in FIG. 50, the example illustrated in FIG. 51 is arranged so that the Y direction widths of fringe patterns FR increase as the X direction distances from the memory-cell region becomes greater. Thus, when forming contacts, it is possible to improve the process capacity in the patterning process step and secure process margin by providing fringe patterns FR elongated in the Y direction.

In addition to the arrangement in which fringe patterns FR are gradually displaced in the same direction, it is further possible to adopt a zigzag arrangement or the like.

### Ninth Embodiment

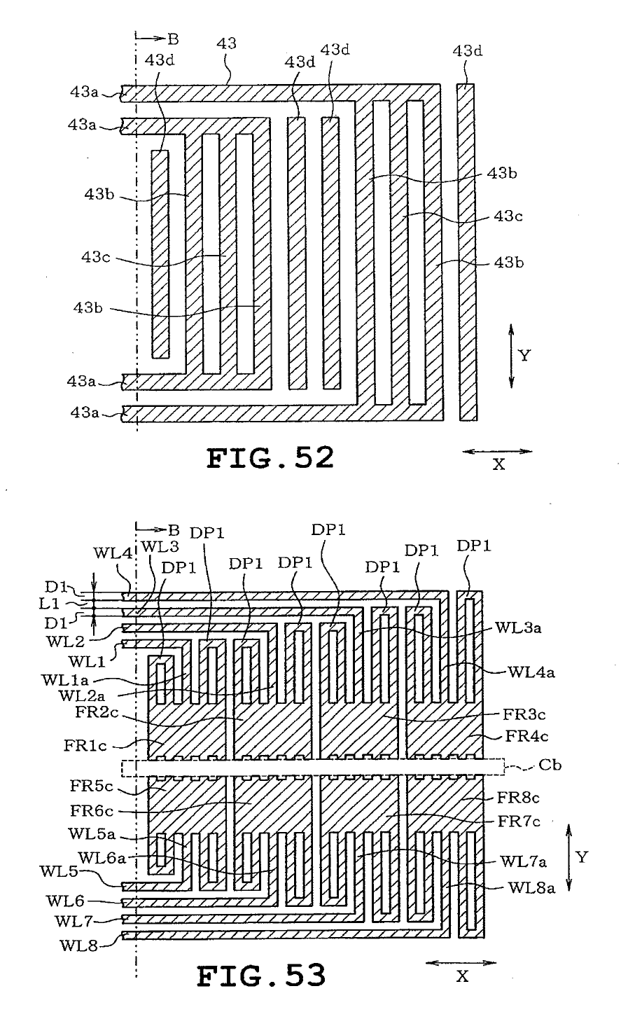

FIGS. 52 and 53 illustrate a ninth embodiment. Description will be given hereinunder based primarily on the differences from the eighth embodiment. The ninth embodiment differs from the eighth embodiment in that dummy pattern DP2 is not provided. That is, as illustrated in FIG. 53, each of fringe patterns FR1 to FR8 is distanced from the adjacent fringe pattern by space L1. As illustrated in the layout of FIG. 53, dummy pattern DP2 is not provided. As a result, the spaces between fringe patterns FR1 to FR8 in the X direction become narrower and thereby provide improved space efficiency.

In the manufacturing process flow, mandrel patterns 43 are used as illustrated in FIG. 52.

Mandrel patterns 43a extend in the X direction and are disposed with a predetermined space from one another in the Y direction. Mandrel patterns 43b extend in the Y direction and are disposed with a predetermined space from one another in the X direction. Two lines of mandrel patterns 43b are connected to each line of mandrel patterns 43a of the word line.

One line of mandrel patterns 43c is disposed in the space located between mandrel patterns 43b aligned in the X direction which are connected to a common mandrel pattern 43a. Mandrel pattern 43c is connected to mandrel pattern 43a in the upper side and mandrel pattern 43a in the lower side.

The width of mandrel pattern 43c is the same as the width of mandrel pattern 43a. Mandrel pattern 43c is equally spaced from mandrel patterns 43b disposed in both X direction sides. Further, two lines of mandrel patterns 43d are disposed in the space located between mandrel patterns 43b aligned in the X direction which are not connected to a common mandrel pattern 43a. Dummy mandrel pattern 43d is neither connected to mandrel pattern 43a in the upper side and mandrel pattern 43a in the lower side. The width of dummy mandrel patterns 43d is the same as the width of mandrel patterns 43a. The space between the two lines of dummy mandrel patterns 43d is equal to the space between mandrel pattern 43b and mandrel pattern 43c adjacent in the X direction.

Then, mandrel patterns 43 are subjected to a slimming process as was the case in the foregoing embodiments. Thereafter, resist patterns corresponding to fringe patterns are formed, whereafter the gate electrode film is processed to obtain the pattern illustrated in FIG. 53.

The ninth embodiment described above also obtains the operation and effect similar to those of the eight embodiment and further achieves improved space efficiency.

### Other Embodiments

The foregoing embodiments may be modified as follows.

The embodiments were described through an example of NAND flash memory device 100, however, other embodiments may be described through examples of other nonvolatile semiconductor storage devices such as NOR flash memory device or EEPROM. The memory cells may be configured as an SLC (single level cell) or a MLC (multilevel cell).

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate having a hook-up region;
wirings extending in a first direction above the semiconductor substrate and being aligned with a first spacing between one another, every two wirings forming pairs of wirings, each pair having a first portion being bent in a second direction different from the first direction in the hook-up region, the wirings of each pair being spaced from one another by a first spacing, the pairs being spaced from one another by a second spacing greater than the first spacing; and
fringe patterns each being formed on a first side of each of the wirings of each of the pairs, the first side facing the second spacing.

2. The device according to claim 1, wherein the fringe patterns of adjacent pairs of wirings are displaced from one another in the second direction.

3. The device according to claim 1, wherein the wirings are formed by performing a sidewall transfer process twice.

4. A method of manufacturing a semiconductor device comprising:
forming a conductive layer serving as a wiring above a semiconductor substrate;
forming a first processing film above the conductive layer and a second processing film above the first processing film;
processing the second processing film into wiring masks extending in a first direction and being spaced from one another by a first spacing, every two wiring masks, spaced from one another by the first spacing and bent in a second direction different from the first direction, being processed into paired wiring masks, each of the paired wiring masks being spaced by a second spacing greater than the first spacing;
forming hook-up masks by patterning a resist film so as to fill gaps between adjacent paired wiring masks;
anisotropically etching the first processing film and the conductive layer using the wiring masks, the paired wiring masks, and the hook-up masks to form wiring patterns, paired wiring patterns, and linked fringe patterns; and
dividing the linked fringe patterns to form fringe patterns.

5. The method according to claim 4, wherein forming hook-up masks includes:
forming a third processing film not filling the first spacing between the wiring masks and the first spacing of each paired wiring masks but filling a spacing being greater than the first spacing,
forming the hook-up masks above the third processing film, and
removing the third processing film using the hook-up masks.

6. The method according to claim 4, wherein the conductive layer is used for forming gate electrodes for memory-cell transistors and select transistors formed above the semiconductor substrate via an insulating film, and
wherein processing the second processing film into wiring masks includes:
forming sidewalls for mandrel patterns serving as the wiring masks, the paired wiring masks, and gate masks for forming the gate electrodes,
forming a fourth processing film, without removing the mandrel patterns, along the wiring masks, the paired wiring masks, and the gate masks so as to fill gaps between the wiring masks and regions for forming the gate electrodes of the select transistors,
etching back the fourth processing film and the mandrel patterns by isotropic etching so that the fourth processing film and the mandrel patterns remain between gaps having the first spacing but are removed from other portions, and
wherein forming hook-up masks forms resist masks in the regions for forming the gate electrodes of the select transistors and in regions for forming the gate electrodes of the memory-cell transistors located on both sides of the regions for forming the gate electrodes of the select transistors, and
wherein anisotropically etching the first processing film and the conductive layer forms the gate electrodes of the memory-cell transistors and gate electrode portions of the select transistors using the resist masks.

7. A semiconductor device comprising:
a semiconductor substrate having a hook-up region;
wirings extending in a first direction above the semiconductor substrate and being aligned with a first spacing between one another, the wirings each having a first portion extending in a second direction different from the first direction in the hook-up region;
fringe patterns each connected to each of the first portions; and
at least one dummy portion disposed in regions where the first portions of the wirings are spread;
a spacing between the fringe patterns in the first direction and a spacing between the fringe patterns and the dummy portion being equal to or less than a first distance.

8. The device according to claim 7, wherein the dummy portion is disposed in a region where two of the wirings in the first portion are isolated.

9. The device according to claim 7, wherein the dummy portion is disposed in a region where two of the wirings in the first portion are spread by bending.

10. The device according to claim 7, wherein a spacing between the wirings and the dummy portion is equal to or less than the first distance.

11. The device according to claim 7, wherein the first distance is equal to or less than 200 nm.

12. The device according to claim 7, wherein the wirings and the fringe patterns are formed using a sidewall transfer technique.

13. A semiconductor device comprising:
a semiconductor substrate having a memory-cell array region and a hook-up region;
wirings disposed in the memory-cell array region and extending in a first direction from the memory-cell array region to the hook-up region, the wirings being aligned with a first spacing between one another and having a first portion extending in a second direction different from the first direction in the hook-up region;
fringe patterns each connected to the first portion, the fringe patterns including a first fringe pattern disposed in a first location being the furthest in the first direction from a boundary between the memory-cell array region and the hook-up region, and a second fringe pattern disposed in a second location adjacent to the first location in the first direction; and
dummy patterns including a first dummy pattern disposed in a third location being further in the first direction from a boundary between the memory-cell array region and the hook-up region than the first location and being adjacent to the first location,
the first fringe pattern and the first dummy pattern being spaced by a distance greater than a distance between the first fringe pattern and the second fringe pattern.

14. A semiconductor substrate comprising:
a semiconductor substrate;
wirings extending in a first direction above the semiconductor substrate and being aligned with a first spacing between one another, every two wirings forming a pair and being bent in a second direction different from the first direction, a first wiring and a second wiring of the pair each having a first portion extending in a direction different from the second direction;
a first dummy pattern having a second portion opposing the first portion of the first wiring in the Y direction;
a second dummy pattern having a third portion opposing the first portion of the second wiring in the Y direction;
a first fringe pattern connected to the first wiring; and
a second fringe pattern connected to the second wiring,
the first portion of the first wiring and the second portion of the first dummy pattern being spaced from one another within a range of optically exposable distance.

15. The device according to claim 14, wherein the first dummy pattern and the first wiring connect to the fringe patterns.

16. A semiconductor substrate comprising:
a semiconductor substrate;
wirings having a first width extending in a first direction above the semiconductor substrate and being aligned with a first spacing between one another;
hook-up parts in which the wirings are bent in a second direction different from the first direction and the wirings are disposed with a second spacing greater than the first spacing;
fringe patterns provided in the hook-up parts and each having a second width greater than the first width; and
at least one dummy portion having the first width provided in a space within the second spacing between the hook-up parts and being spaced in the first direction from the hook-up parts, the dummy portion being disposed parallel with the hook-up parts and being electrically isolated from the hook-up parts.

17. The device according claim 16, wherein the fringe patterns are disposed along the second direction so as to be line-symmetric with respect to a line of symmetry extending along the first direction, and the dummy portion located between the fringe patterns disposed in the second direction is cut.

18. The device according claim 16, wherein two or more dummy portions are provided between the hook-up parts, and one or more dummy portions proximal to the hook-up parts are formed so as to contact the fringe patterns.

19. The device according to claim 18, wherein the one or more dummy portions provided so as to contact the fringe patterns are electrically non-conductive with the dump portion adjacent in the first direction.

20. The device according to claim 16, wherein one or more electrically floating dummy portions are provided between adjacent fringe patterns.
